(19) United States
(12) Patent Application Publication
(10) Pub. No.: US 2025/0390629 A1
(43) Pub. Date: Dec. 25, 2025

(54) SYSTEM AND METHOD TO IMPROVE VISUALIZATION OF VIRTUAL TOOLS AND ASSISTANCE

(71) Applicant: SAMSUNG ELECTRONICS CO., LTD., Suwon-si (KR)

(72) Inventors: Jeyvan VIRIYA, Jakarta (ID); Tandri SURYADI, Jakarta (ID); Kevin WINATA, Jakarta (ID); Andri SETIAWAN, Jakarta (ID); Albertus Dio PADMADHARMA, Jakarta (ID); Hadi PRAWIRATAMA, Jakarta (ID); Yanuar RAHMAN, Jakarta (ID); Farhan Iqbal TAWAKAL, Jakarta (ID); Ayunda TRISTIANTI, Jakarta (ID); Amri SHODIQ, Jakarta (ID); Leonardus Ardyandhita Kurniawan SUWARDHANIS, Jakarta (ID)

(73) Assignee: SAMSUNG ELECTRONICS CO., LTD., Suwon-si (KR)

(21) Appl. No.: 19/244,564

(22) Filed: Jun. 20, 2025

Related U.S. Application Data
(63) Continuation of application No. PCT/KR2025/008434, filed on Jun. 18, 2025.

(30) Foreign Application Priority Data
Jun. 19, 2024 (ID) P00202405511

(51) Int. Cl. G06F 30/18; G16Y 30/00

(52) U.S. Cl. CPC G06F 30/18; G16Y 30/00

(57) ABSTRACT

A method, apparatus, and non-transitory computer-readable medium for enhanced user visualization of Internet of Things (IoT) capabilities of a plurality of IoT devices is provided. The method may include displaying a modular floor plan based on an area associated with a user; mapping a placement of one or more existing IoT devices associated with the user on the modular floor plan; recommending a new IoT device by displaying the new IoT device on the modular floor plan, wherein the new IoT device is compatible with the one or more existing IoT devices; scanning the new IoT device in response to confirmation that the user received the new IoT device; and mapping the new IoT device to an existing placeholder IoT device from the modular floor plan.

### CROSS-REFERENCE TO RELATED APPLICATIONS

This application is a bypass continuation application of International Application No. PCT/KR2025/008434, filed on Jun. 18, 2025, which is based on and claims priority to Indonesian Patent Application No. P00202405511 filed on Jun. 19, 2024, in the Indonesian Patent Office, the disclosures of which are incorporated by reference herein in their entireties.

### BACKGROUND

### 1. Field

The disclosure relates generally to internet of things (IoT) environments and systems and methods for enhancing user visualization, engagement, and experience between environments. More specifically, the disclosure provides a system and method for designing, experiencing, setting up, and receiving recommendations for IoT capabilities. The system utilizes advanced technologies such as IoT, cloud services, virtualization, collaborative filtering, and content-based filtering to enable users to design their own IoT environment, experience it before purchasing, set it up seamlessly, and receive tailored recommendations for devices, automations, and troubleshooting methods.

### 2. Description of Related Art

The IoT industry is a growing industry which has a huge amount of manufacturers, ranging from enormous electronic firms to startups, all making various ground-breaking contributions to the industry. Therefore, there are many new product releases and updates within short periods of time, increasing both the variety of products and possible interactions available for the users. According to some estimates, there are well over 14 billion connected IoT devices around the globe and it's expected there will be 25.44 billion IoT devices by 2030.

Due to the rapid growth in the IoT industry, and the users' limited research capacity, they may be a disparity of information regarding the latest updates and the users' last known information. This could be an issue when a user is trying to start using IoT devices and/or the user is trying to enhance their current IoT environments as they would find setbacks in finding and implementing the optimal device for their environment.

Currently, both new users willing to implement new IoT devices within their spaces, and those wanting to fully utilize their currently available IoT devices by adding additional devices, are unable to experience—roughly know the feeling of implementing the IoT devices they are interested in—both in terms of possible automations and device functionalities, without actually buying the physical devices. If users are given the opportunity to visualize possible automations and device functionalities, users would be able to foresee the possible interactions, motivating purchase.

Another issue related to the previous background is that the information sources for the different IoT systems are diversely scattered, in a way that for a similar type of device, there could be different variations of information relating to that specific device, due to difference in manufacturer, producer, and specifications.

Finally, it could be troublesome to check for compatibility between one device with an existing system, or vice versa. Additionally, certain devices have specific prerequisites that is needed to be satisfied for it to be able to function properly (e.g. Sensor A needs a Matter Hub). Given the condition that the technical information regarding these specifications are vastly scattered, it could be troublesome to maintain the stability of the user's IoT Environment (cross-compatibility, etc.).

Accordingly, systems and methods to improve IoT user visualization, engagement and experience using virtual tool and assistance are needed. Furthermore, systems and methods that encompass a complete system of design, virtual real visualization experience, set up and recommendation of IoT devices are needed.

Related art does not disclose an IoT visualization and experience toolset comprising of room designing, virtual and real device experience, integrated purchasing, automatic device setup and contextual recommendation. A system and method that offers a holistic approach to IoT devices and virtual experiences is needed instead of systems focusing on individual aspects such as augmented reality, recommendation engines, or 3D floor plans.

### SUMMARY

This disclosure provides a method, apparatus, electronic device, and non-transitory computer readable medium for enhanced user visualization of internet of things (IoT) capabilities of a plurality of IoT devices is provided. The apparatus may include memory storing instructions; and at least one processor. The instructions may be configured to, when executed by the at least one processor, cause the apparatus to: display a modular floor plan based on an area associated with a user; map placement of one or more existing IoT devices associated with the user on the modular floor plan; recommend a new IoT device by displaying the new IoT device on the modular floor plan, wherein the new IoT device is compatible with the one or more existing IoT devices; scan the new IoT device in response to confirmation that the user received the new IoT device; and map the new IoT device to an existing placeholder IoT device from the modular floor plan.

A method for enhanced user visualization of internet of things (IoT) capabilities of a plurality of IoT devices is provided. The method may be executed by at least one processor, and the method may include displaying a modular floor plan based on an area associated with a user; mapping placement of one or more existing IoT devices associated with the user on the modular floor plan; recommending a new IoT device by displaying the new IoT device on the modular floor plan, wherein the new IoT device is compatible with the one or more existing IoT devices; scanning the new IoT device in response to confirmation that the user received the new IoT device; and mapping the new IoT device to an existing placeholder IoT device from the modular floor plan.

A non-transitory computer readable medium storing instructions is provided. The instructions, when executed by at least one processor for enhanced user visualization of internet of things (IoT) capabilities of a plurality of IoT devices, cause the at least one processor to display a modular floor plan based on an area associated with a user; map placement of one or more existing IoT devices associated with the user on the modular floor plan; recommend a new IoT device by displaying the new IoT device on the modular floor plan, wherein the new IoT device is compatible with the one or more existing IoT devices; scan the new IoT device in response to confirmation that the user received the new IoT device; and map the new IoT device to an existing placeholder IoT device from the modular floor plan.

### BRIEF DESCRIPTION OF THE DRAWINGS

To understand the disclosure and to see how the disclosure can be implemented in practice, some embodiments will be described regarding the accompanying drawings, wherein:

FIG. 1 is is a block diagram of IoT visualization and experience enhancement system, according to an embodiment of the disclosure.

FIG. 2 is a diagram of an architecture stack of IoT visualization and experience enhancement system, according to an embodiment of the discloure.

FIG. 3 is a diagram illustrating a process of IoT visualization and experience enhancement system for user space management, according to an embodiment of the discloure.

FIG. 4 is a diagram illustrating IoT visualization and experience enhancement system import space layout from floor plan.

FIG. 5 is an exemplary implementation of a user interface, according to an embodiment of the discloure.

FIG. 6 is an exemplary implementation of a user interface, according to an embodiment of the discloure.

FIG. 7 is an exemplary implementation of a user interface, according to an embodiment of the discloure.

FIG. 8 is an exemplary implementation of a user interface, according to an embodiment of the discloure.

FIG. 9 is an exemplary implementation of a user interface, according to an embodiment of the discloure.

FIG. 10 is an exemplary implementation of a user interface, according to an embodiment of the discloure.

FIG. 11 is an exemplary implementation of a user interface, according to an embodiment of the discloure.

FIG. 12 is an exemplary implementation of a user interface, according to an embodiment of the discloure.

FIG. 13 is an exemplary implementation of a user interface, according to an embodiment of the discloure.

FIG. 14 is an exemplary implementation of a user interface, according to an embodiment of the discloure.

FIG. 15 is an exemplary implementation of a user interface, according to an embodiment of the discloure.

FIG. 16 is an exemplary implementation of a user interface, according to an embodiment of the discloure.

FIG. 17 is a diagram of a process of IoT visualization and experience enhancement system for device placement management, according to an embodiment of the discloure.

FIG. 18 is an exemplary implementation of a user interface for device placement, according to an embodiment of the discloure.

FIG. 19 is an exemplary implementation of a user interface for device placement, according to an embodiment of the discloure.

FIG. 20 is a diagram of a process of IoT visualization and experience enhancement system for state synchronization.

FIG. 21 is a diagram illustrating an exemplary implementation IoT visualization and experience enhancement system, according to an embodiment of the discloure.

FIG. 22 is an exemplary implementation of a user interface, according to an embodiment of the discloure.

FIG. 23 is an exemplary implementation of a user interface, according to an embodiment of the discloure.

FIG. 24 is an exemplary implementation of a user interface, according to an embodiment of the discloure.

FIG. 25 is an exemplary implementation of a user interface, according to an embodiment of the discloure.

FIG. 26 is an exemplary implementation of a user interface, according to an embodiment of the discloure.

FIG. 27 is an exemplary implementation of a user interface, according to an embodiment of the discloure.

FIG. 28 is an exemplary implementation of a user interface, according to an embodiment of the discloure.

FIG. 29 is an exemplary implementation of a user interface, according to an embodiment of the discloure.

FIG. 30 is a diagram of a process of IoT visualization and experience enhancement system for managing set up, according to an embodiment of the discloure.

FIG. 31 is an exemplary implementation of a user interface, according to an embodiment of the discloure.

FIG. 32 is an exemplary implementation of a user interface, according to an embodiment of the discloure.

FIG. 33 is an exemplary implementation of a user interface, according to an embodiment of the discloure.

FIG. 34 is an exemplary implementation of a user interface, according to an embodiment of the discloure.

FIG. 35 is a diagram of a process of IoT visualization and experience enhancement system for an IoT AI recommendation subsystem.

FIG. 36 is an exemplary implementation of a user interface, according to an embodiment of the discloure.

FIG. 37 is an exemplary implementation of a user interface, according to an embodiment of the discloure.

FIG. 38 is an exemplary implementation of a user interface, according to an embodiment of the discloure.

FIG. 39 is an exemplary implementation of a user interface, according to an embodiment of the discloure.

FIG. 40 is an exemplary implementation of a user interface, according to an embodiment of the discloure.

FIG. 41 is an exemplary implementation of a user interface, according to an embodiment of the discloure.

FIG. 42 is an exemplary implementation of a user interface, according to an embodiment of the discloure.

FIG. 43 is an exemplary implementation of a user interface, according to an embodiment of the discloure.

FIG. 44 is an exemplary implementation of a user interface, according to an embodiment of the discloure.

FIG. 45 is an exemplary implementation of a user interface, according to an embodiment of the discloure.

FIG. 46 is an exemplary implementation of a user interface, according to an embodiment of the discloure.

FIG. 47 is an exemplary implementation of a user interface, according to an embodiment of the discloure.

FIG. 48 is an exemplary implementation of a user interface, according to an embodiment of the discloure.

FIG. 49A is a diagram of a use case illustrating a process for developing a smart infrastructure such as home, apartments, building, etc, according to an embodiment of the discloure.

FIG. 49B is a diagram of a use case illustrating a process for developing a smart infrastructure such as home, apartments, building, etc, according to an embodiment of the discloure.

FIG. 50 is a diagram of a use case illustrating maintenance of currently available iot devices and enhancement of user's iot visualization and experience, according to an embodiment of the discloure.

FIG. 51 is a diagram of a use case illustrating customization of user's iot environment according to specific goals, according to an embodiment of the discloure.

### DETAILED DESCRIPTION

Embodiments of the disclosure provide recommendations to users on potential devices, automations, routines, setups, and other aspects aligned with their specified goals. These recommendations are generated based on factors such as user preferences, device compatibility, and overall efficiency.

Embodiments of the disclosure enable users to design their virtual spaces using virtual devices, taken from generated recommendations or individual preferences, enhancing flexibility and customization options for users.

Embodiments of the disclosure facilitate the integration of virtual devices into the user's existing IoT environment, allowing users to visualize and/or experience automations and routines involving both their physical devices and the added virtual devices. This seamless blending of virtual and physical devices enhances the overall user visualization.

Embodiments of the disclosure connect users directly to online or physical stores where they can purchase desired devices, reducing the time required to acquire new devices.

Embodiments of the disclosure assist users in setting up newly purchased devices by mapping previously added virtual devices, along with their associated automations and configurations, onto the newly acquired devices, ensuring a smooth transition and minimizes the effort required for device integration.

In the following description, numerous specific details are set forth in order to provide a thorough understanding of the disclosure. It will be apparent, however, to one skilled in the art that these specific details are only examples and not intended to be limiting. Additionally, it may be noted that the systems and/or methods are shown in block diagram form only in order to avoid obscuring the disclosure. It is to be understood that various omissions and substitutions of equivalents may be made as circumstances may suggest or render expedient to cover various applications or implementations without departing from the spirit or the scope of the disclosure. Further, it is to be understood that the phraseology and terminology employed herein are for the purpose of clarity of the description and should not be regarded as limiting.

Furthermore, in the description, references to “one embodiment” or “an embodiment” means that a particular feature, structure, or characteristic described in connection with the embodiment is included in at least one embodiment of the disclosure. The appearance of the phrase “in one embodiment” in various places in the specification is not necessarily referring to the same embodiment, nor are separate or alternative embodiments mutually exclusive of other embodiments. Further, the terms “a” and “an” used herein do not denote a limitation of quantity, but rather denote the presence of at least one of the referenced items. Moreover, various features are described which may be exhibited by some embodiments and not by others. Similarly, various requirements are described, which may be requirements for some embodiments but not for other embodiments.

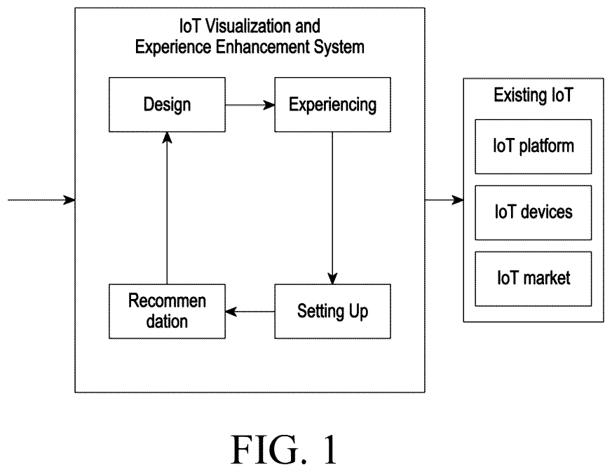

At least one of the components, elements, modules and units (collectively “components” in this paragraph) represented by a block in the drawings such as FIGS. 1, 2, 20, 49A, 49B, 50, and 51 may use a direct circuit structure, such as a memory, a processor, a logic circuit, a look-up table, etc. that may execute the respective functions through controls of one or more microprocessors or other control apparatuses. Also, at least one of these components may be specifically embodied by a module, a program, or a part of code, which contains one or more executable instructions for performing specified logic functions, and executed by one or more microprocessors or other control apparatuses. Further, at least one of these components may include or may be implemented by a processor such as a central processing unit (CPU), a microprocessor, or the like that performs the respective functions.

Various modules according to embodiments of the disclosure may be implemented by memory storing instructions and one or more processors configured to execute the instructions. The one or more processors may include one or more of a central processing unit (CPU), a graphics processing unit (GPU), an accelerated processing unit (APU), a many integrated core (MIC), a field-programmable gate array (FPGA), a digital signal processor (DSP), a neural processing unit (NPU), a hardware accelerator, or a machine learning accelerator. The one or more processors are able to perform control of any one or any combination of the other components of the computing device, and/or perform an operation or data processing relating to communication. The one or more processors execute one or more programs stored in a memory.

The one or more processors may be implemented as one or more multi-core processors that include one or more cores (e.g., homogeneous multi-cores or heterogeneous multi-cores). When a plurality of cores are included in a processor, each of the cores may include a cache memory, and a common cache shared by the cores may be included in the processor. Each of the cores may independently read and execute program instructions or each of the cores may read and execute one or more portions of program instructions.

In embodiments of the disclosure, a processor may refer to a system-on-a-chip (SoC) in which one or more cores and other electronic components are integrated, a single core processor, a multicore processor, or a core included in the single core processor or the multicore processor, wherein the core may be implemented as a CPU, a GPU, an APU, an MIC, an FPGA, a DSP, an NPU, a hardware accelerator, or a machine learning accelerator, but the embodiments of the disclosure are not limited thereto.

Computer instructions for performing a processing operation in the systems such as FIGS. 1, 2, 20, 49A, 49B, 50, and 51 according to certain embodiments of the disclosure described above may be stored in a non-transitory computer-readable medium. When the computer instructions stored in the non-transitory computer-readable medium are executed by a processor of a specific device, the specific device described above performs the processing operation in the apparatus according to certain embodiments described above.

The non-transitory computer readable recording medium refers to a medium that stores data and that can be read by devices. In detail, the above-described various applications or programs may be stored in the non-transitory computer readable medium, for example, a compact disc (CD), a digital versatile disc (DVD), a hard disc, a Blu-ray disc, a universal serial bus (USB), a memory card, a ROM, and the like, and may be provided.

Preferred embodiments and their advantages are best understood by referring to FIGS. 1 through 51. Accordingly, it is to be understood that the embodiments of the disclosure herein described are merely illustrative of the application of the principles of the invention. Reference herein to details of the illustrated embodiments is not intended to limit the scope of the claims, which themselves recite those features regarded as essential to the invention. Within the figure, the terms wireframe is use to represent a diagram that consists of simple lines and shapes representing the framework of application user interface (UI) and core functionality.

Referring now to FIG. 1, the disclosure relates to a system for enhancing user visualization, engagement, and experience in IoT capabilities. As shown in FIG. 1, the IoT visualization and experience enhancement system may include subsystems for designing, experiencing, setting up, and recommendation, which are connected to an existing IoT ecosystem including IoT platforms, IoT devices, and IoT marketplaces. The design subsystem may include floor plan management, device placement, home planner, and automatic placement recommendation functions. The experiencing subsystem may host virtual devices connecting to existing IoT platforms and may provide an automation experiencing interface capable of connecting with both virtual and real devices. The setting up subsystem may handle purchasing through the IoT marketplace, detects newly purchased devices, assists with the setup process using virtual devices, and maps placeholders to actual devices. The recommendation subsystem may suggest improvements to the user's IoT visualization and experience based on their current devices, including recommendations for automations and new devices.

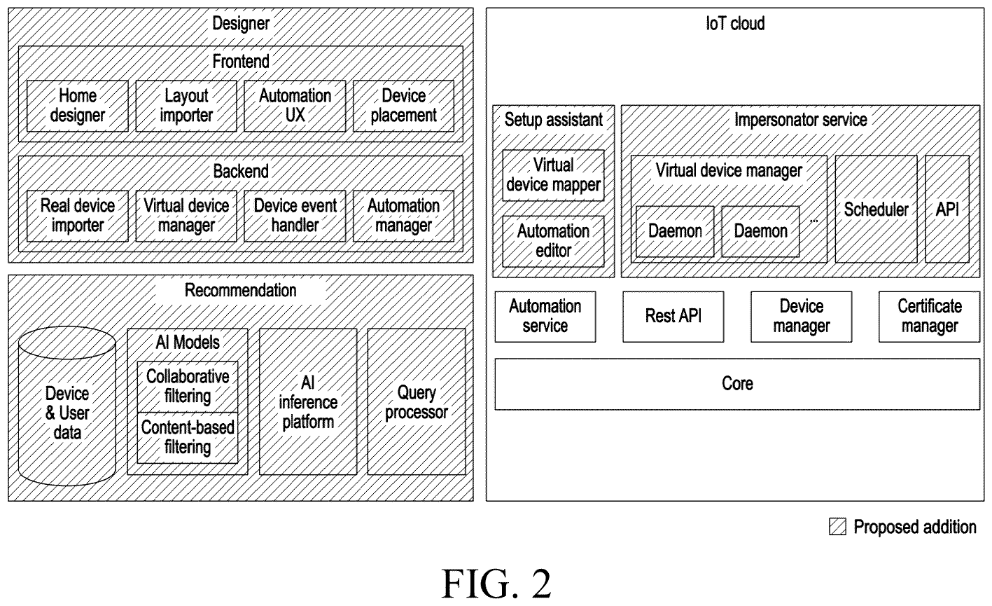

Referring now to FIG. 2, the architectural stack for the IoT visualization and experience enhancement system may include additional components compared to the related system. Typical IoT cloud contains several services, including automation, REST APIs, device managers, and certificate managers. To implement the proposed user visualization and experience enhancement system, the current IoT cloud requires additional components to support the proposed virtual devices, automations, and actions. A new impersonator service may be implemented, including virtual device managers, which may generate execution daemons for the virtual devices, a scheduler for automated virtual device actions, and APIs for virtual device connections. Additionally, a setup assistant for virtual devices may be added to the iot cloud, including virtual device mappers to map virtual devices to physical devices when available and an automation editor for customizing virtual device automations. Furthermore, two new platforms must be established to support the design and recommendation subsystems.

For the design subsystem, the new platform must accommodate the entire user interactions and the design process within the Frontend, including a home designer, layout importer, automation ux, which is also essential for the visualization and experiencing stage of the experience sub-system, and the device placement mechanism to facilitate the user with placing their virtual devices. The backend needs to fulfill device management according to user input, including physical and virtual devices. It should include a real device importer service to allows import of the user's currently available physical devices into the platform, virtual device manager to initiate execution of the virtual devices, device event handlers or automation managers for both physical and virtual devices.

For the recommendation subsystem, it requires an AI recommendation model to suggest devices for users. The model may be collaborative or content-based filtering models trained using device and user data and other data sources. Besides the model itself, the recommendation subsystem also requires stored device and user data, an AI inference platform containing the model accessible by the system for case-by-case recommendations tailored to the user's IoT environment, and a query processor handling system queries regarding specific device recommendations.

The system may consist of four subsystem modules. First is design subsystem which consists of three categorizations: user space management, device placement, and home planner. Second is experiencing subsystem (also referred to as visualization and experience system) to host virtual devices in existing platform and allow users get experience of user space in reality and virtual device interaction. Third is setting up subsystem to allow device acquisition, mapping and setup within the system. Fourth recommendation subsystem to suggest user IoT visualization and experience based on user's devices including automations, routines, new devices, and device setups.

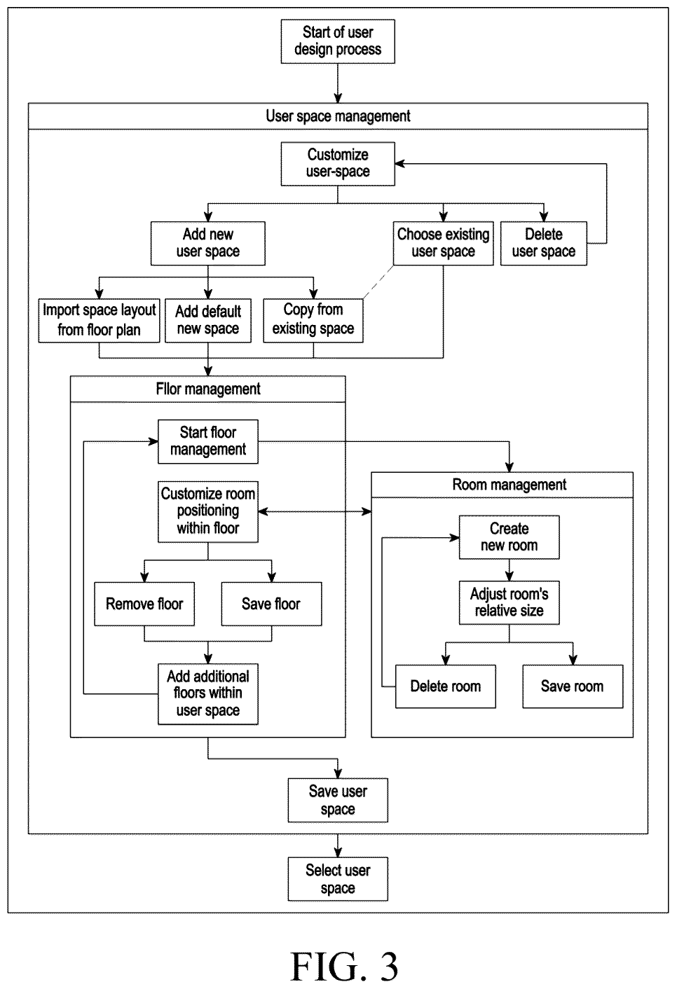

FIG. 3 is the user space management. The user's space may refer to an entire area, e.g., the user's living area, which may consist of multiple spaces. Users may add a new space by importing a floor plan document, duplicating an existing space, or creating one from scratch. Each space may contain floors with rooms, and a single space may have multiple floors. A user may customize a user space by generating a modular floor plan or importing a modular floor plan that is based on an area associated with the user. The floors and rooms are depicted as rectangles with adjustable heights and widths, and each room must adjoin another room. When a user creates a new space, at least one space with one floor and one room is generated. Users may label the room as a living room, kitchen, or other designation and move or remove it as needed.

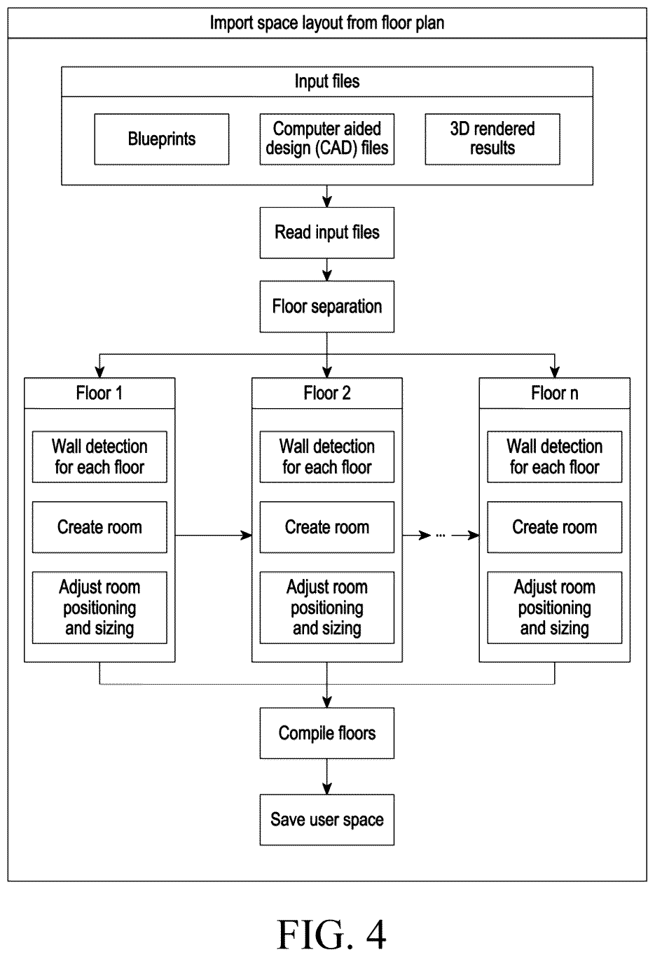

FIG. 4 is the import space layout from the floor plan. The process starts from when a user selects to import a space layout, the system prompts them to upload a file. The system accepts floor layout plans in formats such as blueprints, computer aided design (CAD) files, or 3D render results. After uploading the file, the system reads it and begins processing. First, it separates the floorplan into different floors, which are typically disjointed, i.e., each page represents a floor. Next, the system processes each floor image into floor data. For each floor, it detects walls that separate rooms and creates room data based on those walls. As mentioned earlier, rooms are represented as rectangular shapes. The system compiles the detected rooms, adjusting their positioning and relative sizes. Once all floors are processed, the system arranges them based on their detected positions and saves the final result into the user's space.

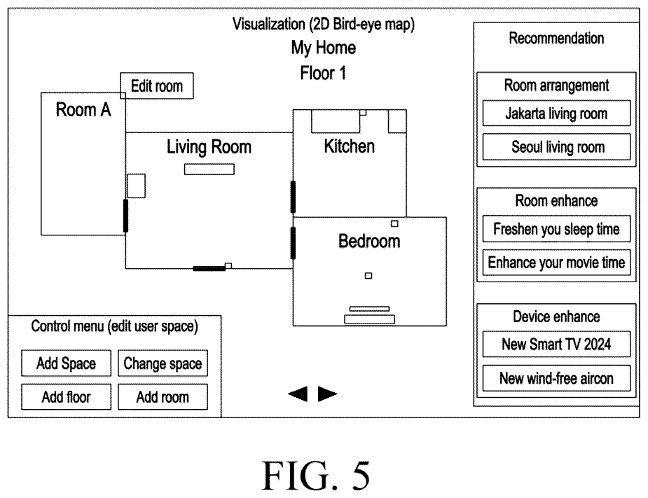

FIG. 5 is the main screen UI wireframe on a visualization 2D bird-eye map. This figure shows a sample implementation of the main screen for the system, representing the user space on a 2-dimensional bird's-eye-view layout, where each floor contains multiple rooms and each room is represented by a single square, and corresponding IoT devices are represented based on their relative positions in each room. The sample recommendations, including room arrangements, room enhancements, and device enhancements, are shown on the right tab, with user capabilities are given in the control menu at the bottom tab. To be noted that the System implementation is not limited to the following layout, but acts as a mere example.

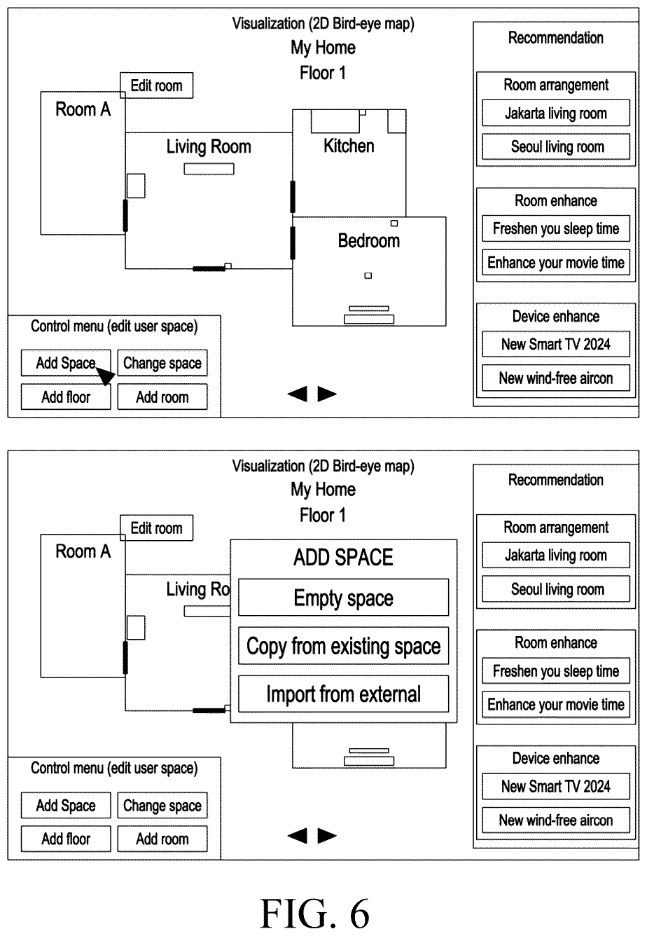

FIG. 6 is the main screen UI wireframe on a visualization 2D bird-eye map. This figure shows a sample of adding a new user space, where the function is initialized by clicking on the “Add Space” button within the control menu at the bottom of the screen in the sample implementation, which will trigger a popup that prompts the user on the method for creating the new user space, which may include adding a new “Empty Space”, copy from the user's other existing space(s), and import from external sources.

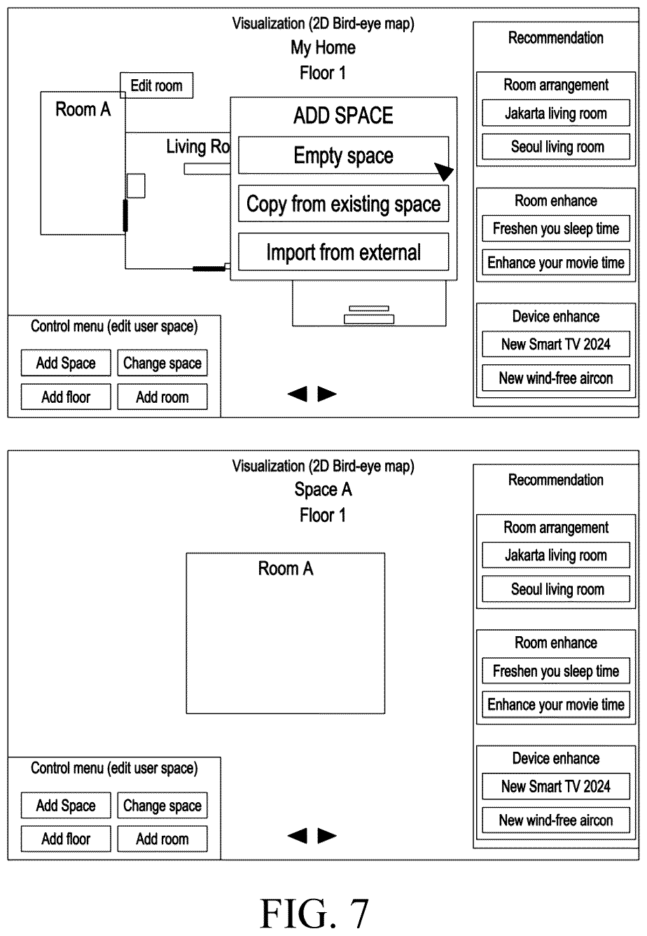

FIG. 7 is the main screen UI wireframe on a visualization 2D bird-eye map. The above figure shows the event when the user chooses to add a new space based on an empty space. By default, adding an empty space creates a new user space with a single floor, consisting of a single room. The event is initiated when the user clicks on the “Empty Space” within the “Add Space” prompt in the sample implementation.

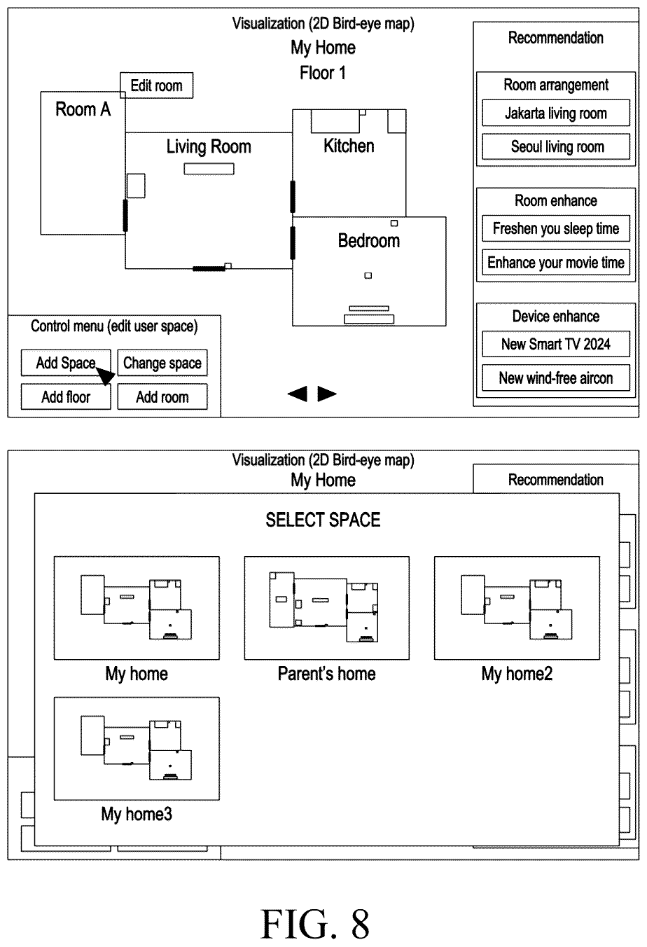

FIG. 8 is the main screen UI wireframe on a visualization 2D bird-eye map. This figure shows the event when the user chooses to add a new space based on the user's current existing space(s). Once the user selects the option “Copy from Existing Space” in the sample implementation, the system will show a popup of all the spaces the user has already customized; in which the user could select the space to be copied as a new space. The process results in a user space similar to the selected space, with the number of floors and rooms within being identical.

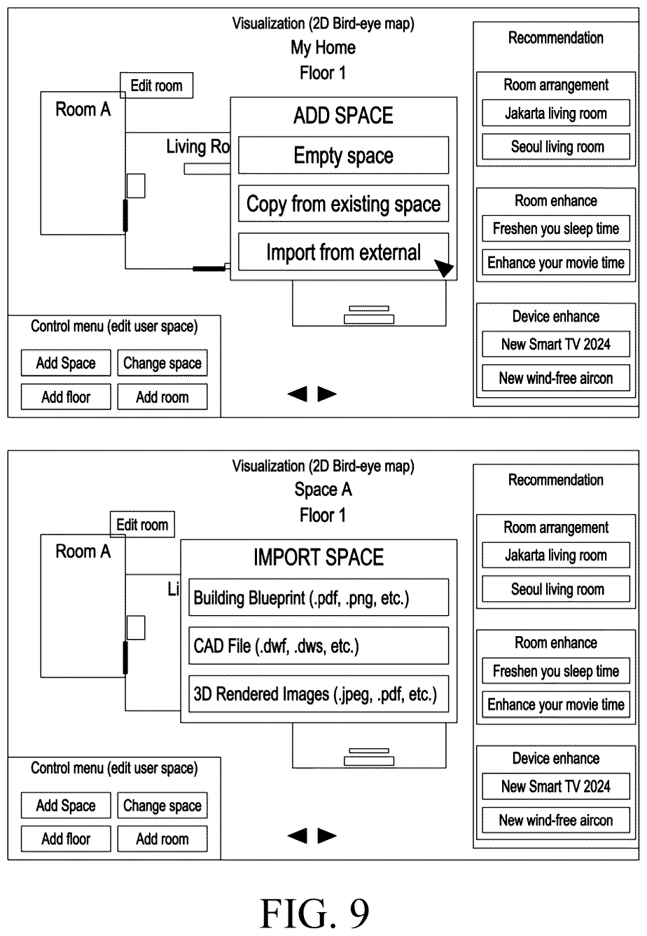

FIG. 9 is the main screen UI wireframe on a visualization 2D bird-eye map. This figure shows the event when the user chooses to add a new space based on an external source. The external sources available for import could include (but not limited to) blueprints, computer-aided-design (CAD) Files, and 3D rendered Images, with the file format being of the corresponding source type. These options are available in the “Import Space” popup that shows after the user clicks the option “Import from External” in the sample implementation. After the import process is complete, the user would have a space with the number of floors and rooms along with their layouts based on the imported media.

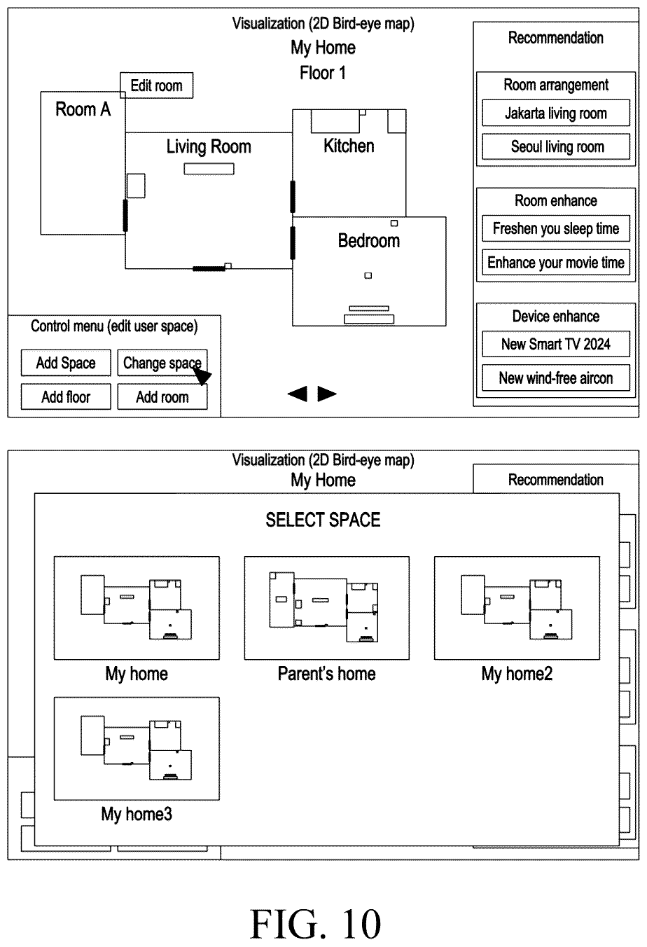

FIG. 10 is the main screen UI wireframe on a visualization 2D bird-eye map. This figure shows the event when the user wants to change the currently shown space. This is done by clicking the “Change Space” option within the control menu at the bottom tab in the sample implementation, which will trigger a popup showing all the spaces that has been customized by the user, allowing the user to select another space to customize.

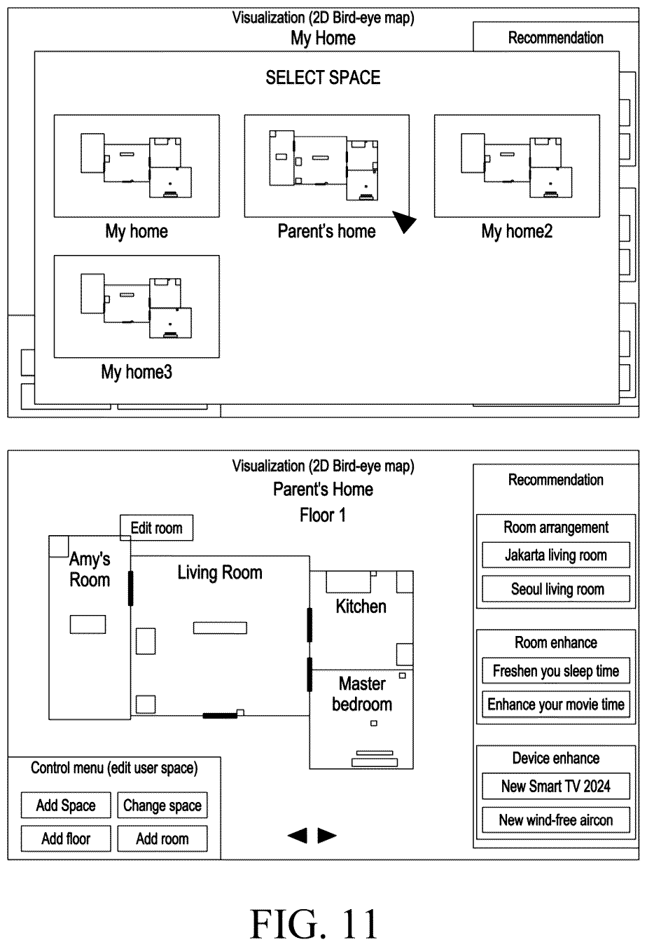

FIG. 11 is the main screen UI wireframe on a visualization 2D bird-eye map. This figure shows the event when the user wants to select the space to edit in the sample implementation. Once the user has selected one of the previously customized space in the given popup, the selected space would be highlighted on the main screen, allowing it to be edited by the user.

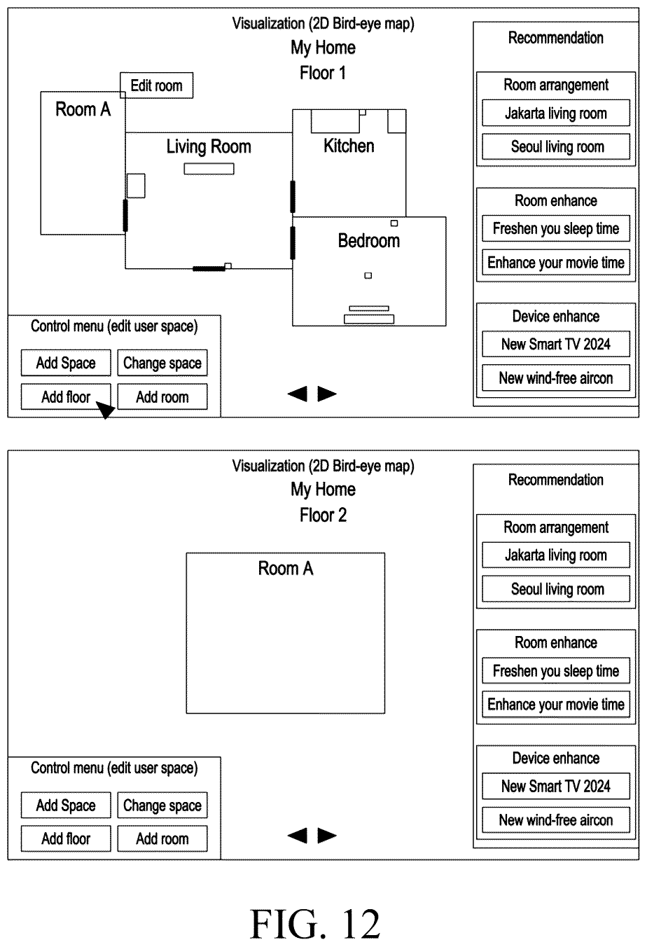

FIG. 12 is the main screen UI wireframe on a visualization 2D bird-eye map. This figure shows the event when the user chooses to add a new floor. The layout would automatically highlight the new floor with the next numbering as the floor name, and a new default floor will be created. A default floor is defined by a single floor with a single room and no devices. This feature may be accessed by clicking the “Add Floor” button from the control menu at the bottom tab in the sample implementation.

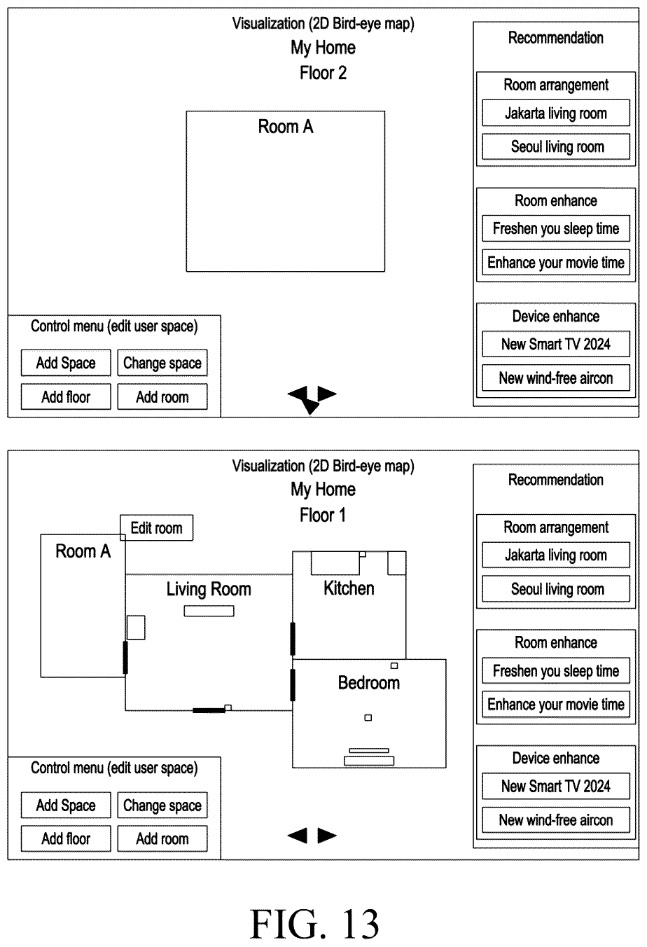

FIG. 13 is the main screen UI wireframe on a visualization 2D bird-eye map. This figure shows the event when the user chooses to move to the previous floor in the sample implementation, which could be done by clicking the left arrow, which would be active in color when a previous page is available. Once this action is executed, the previous floor will be highlighted on the main screen.

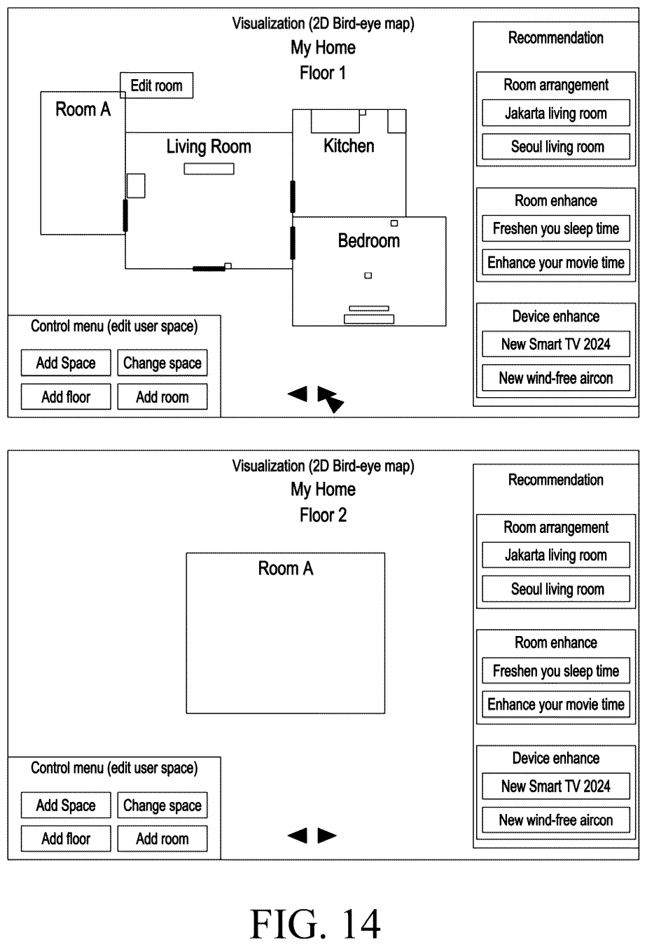

FIG. 14 is the main screen UI wireframe on a visualization 2D bird-eye map. This figure shows the event when the user chooses to move to the next floor in the sample implementation, which could be done by clicking the right arrow, which would be active in color when a next page is available. Once this action is executed, the next floor will be highlighted on the main screen.

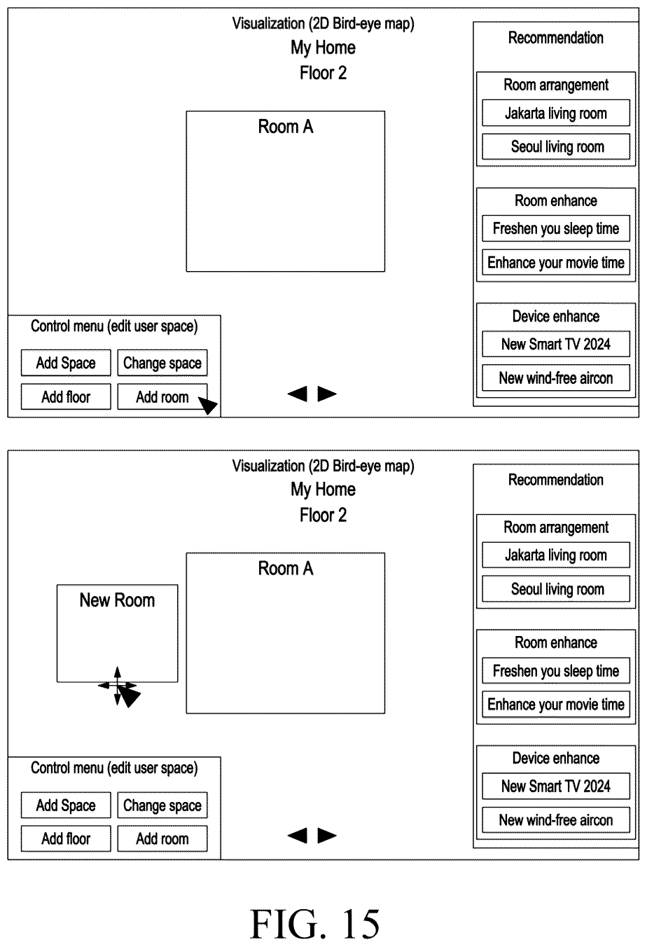

FIG. 15 is the main screen UI wireframe on a visualization 2D bird-eye map. This figure shows the event when the user chooses to add a new room. The new room would be in the form of a square, with the default name “New Room”, and the user would be able to move the room anywhere in the space with a condition that the new room must be connected to another room within the space. This action could be triggered by clicking the “Add Room” button in the control menu at the bottom tab in the sample implementation.

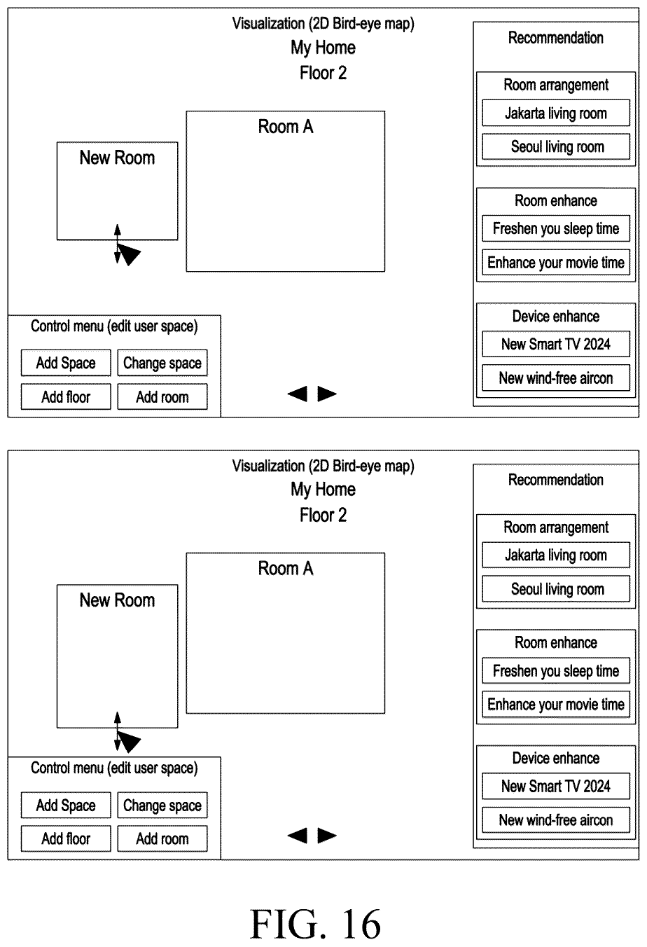

FIG. 16 is the main screen UI wireframe on a visualization 2D bird-eye map. This figure shows the event when the user chooses to edit room dimensions. Once the user selects the room which dimensions would be updated, the user could directly scale the room's dimensions (width and height) as a relative representation of the actual room within their physical space.

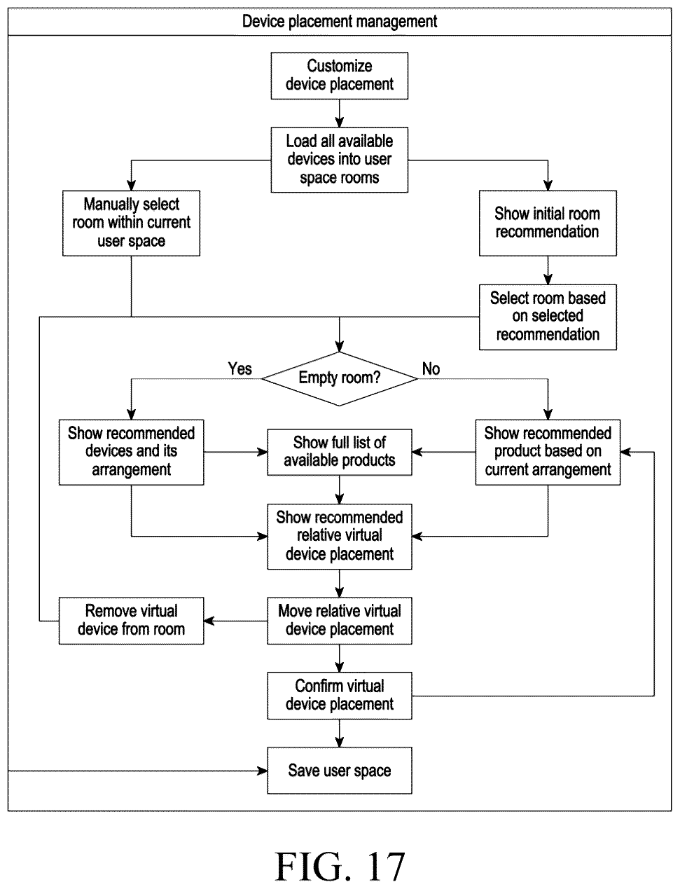

FIG. 17 is the flow process of device placement management. It is a subsystem that may assist users in adding and arranging devices. In the user space, the system displays all devices, including both real and virtual ones. It offers an initial recommendation based on the user's devices. Users may either accept the recommendation, focusing on the suggested room, or manually select a room based on their preference.

The system checks if the chosen room is empty. If it is, the system obtains a room arrangement recommendation, displaying recommended device sets for the room. If the room is not empty, the system suggests additional devices or updates based on the current room arrangement and existing devices. Regardless, users may manually browse the product list. Upon selecting a device or set of devices, the system positions the device in the recommended location (e.g., a soundbar near a TV). Users may move devices or device sets around the room and choose to remove them. If a device is removed, the system checks if the room is empty and provides recommendations accordingly.

Once the user is satisfied with the device's location, they may confirm its position. The added device is a virtual device. Users may continue designing or selecting devices to move around, with the system providing ongoing recommendations based on the current setup. They may proceed to the experiencing subsystem to evaluate the current device placement design. Finally, users may save the design and move to the Setting Up subsystem to purchase the devices.

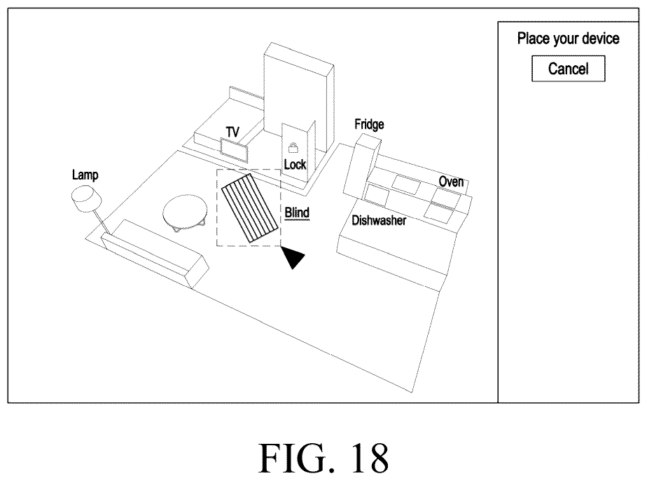

FIG. 18 is the device placement UI wireframe. This figure shows a sample implementation of the device placement mechanism for the system, representing the user space on a 2.5-dimensional layout, where the sample shows a room which contains multiple IoT devices, placed on a relative position upon each other. It is shown that a smart blind is selected and is currently being placed within the room. This is done by highlighting the smart blind in comparison to the other items within the room. This type of representation is another form of possible representation of the layout, being an alternative form of implementation for the system as a whole.

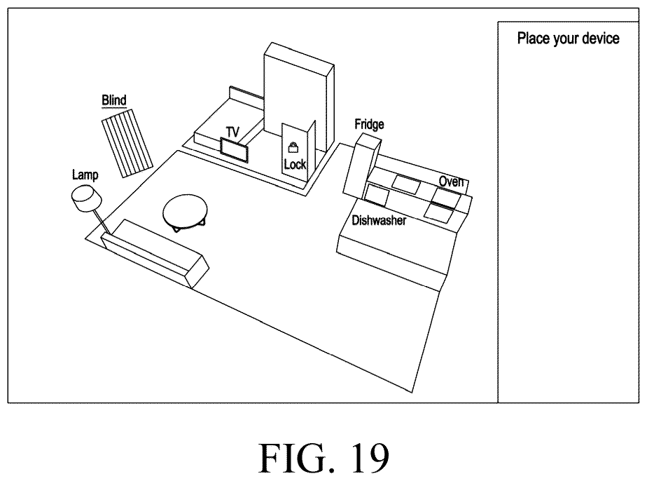

FIG. 19 is the device placement UI wireframe. This figure shows a sample implementation of the device placement mechanism, and a clear overview of a sample implementation in the form of a 2.5 dimensional space for the system, especially after completing the placement of devices, for which the user could confirm the customized device placements.

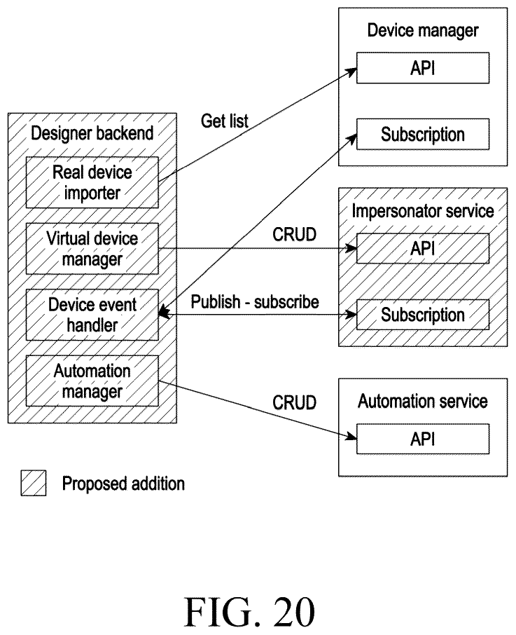

FIG. 20 is the experience sub system state synchronization. The experience subsystem hosts virtual devices, connecting them to existing platforms and offering an automated interface for seamless integration with both real and virtual devices. Key features include the real device importer, which retrieves user device lists using GET APIs from the device manager, virtual device management that utilizes APIs from the Impersonator service for creating, modifying, and deleting virtual devices, the automation manager that employs APIs from the automation service for managing automation processes, and the device event handling feature that monitors and responds to state changes in real and virtual devices by subscribing to the device manager and impersonator service via MQTT or server sent events.

In the figure, user space refers to the IoT environment belonging to the user account within the recommendation application, separate from the IoT platform application. User IoT platform represents the IoT environment managed under the user's account on the IoT platform application in real-world conditions. Automation denotes a pre-designed logical flow operating with paired devices within the IoT environment.

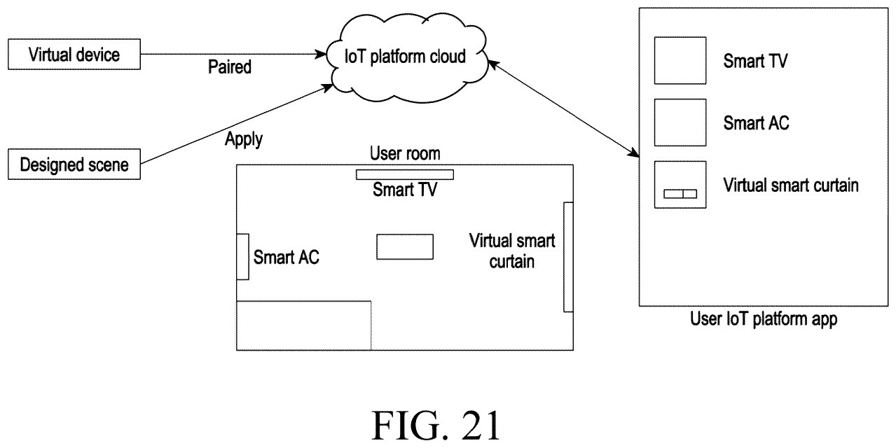

FIG. 21 is the experience subsystem use case. The system shall be capable of integrating both virtual and real devices, enabling the implementation of automation within the user space containing virtual devices. Upon activation of the automation process, virtual devices may coexist and function alongside real devices in the user space. Users must design the automation process considering the devices present within their respective user spaces, fostering an immersive automation interface experience. For instance, a user possesses real devices such as a smart TV and smart AC, creates a virtual device called smart curtain, and applies the “Watch-Movie” automation interface in their user space. Consequently, when the TV is turned on, the AC automatically activates, sets the temperature to 25° C., and the virtual smart curtain closes, providing a seamless user experience. Simultaneously, the IoT platform App displays indicators reflecting the state of the virtual smart curtain.

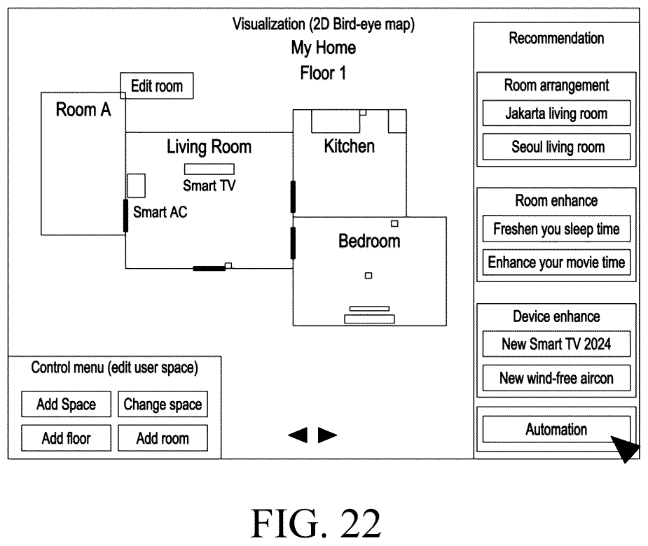

FIG. 22 is the experience UI wireframe. This figure shows the start of automation recommendation, where based on the given recommendations within the right tab, the user would be able to select recommendations for initializing their custom automations, edit or further customize the recommended automations, and run the automations. In this subsystem, the users could also initiate virtual devices to fully experience the automation recommendations given. When the automations are ran, both the user's physical and virtual devices will execute their respective roles, indulging the user with a combined IoT visualization and experience.

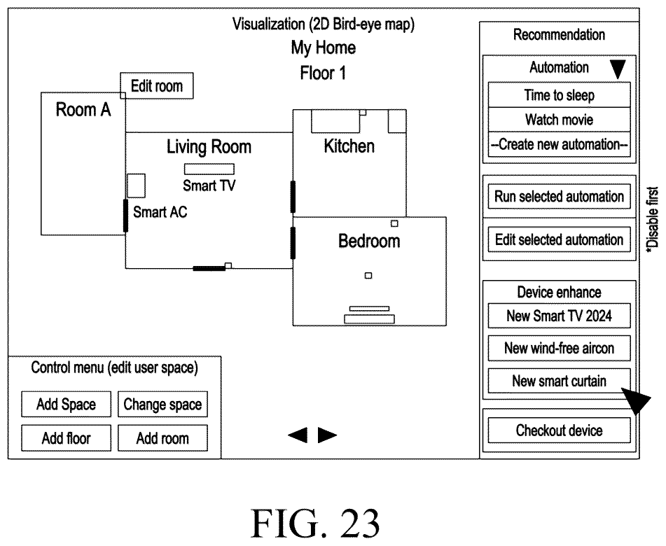

FIG. 23 is the experience UI wireframe. This figure shows the process when the user creates a new virtual device based on device enhancement recommendations. When a user selects a device enhancements recommendation, a new corresponding virtual device will be available for placement within the user space. In the given case, the user selects a “New Smart Curtain” to placed within the user space.

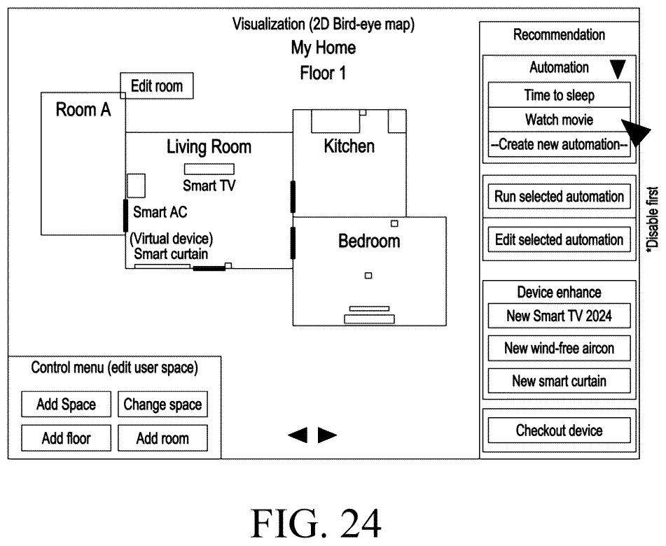

FIG. 24 is the experience UI wireframe. This figure shows the process when the user selects an automation recommendation. Upon placing the new virtual devices within the user space, the user would have the option to select given automation recommendations. In this case, the user selects the “Watch a Movie” automation.

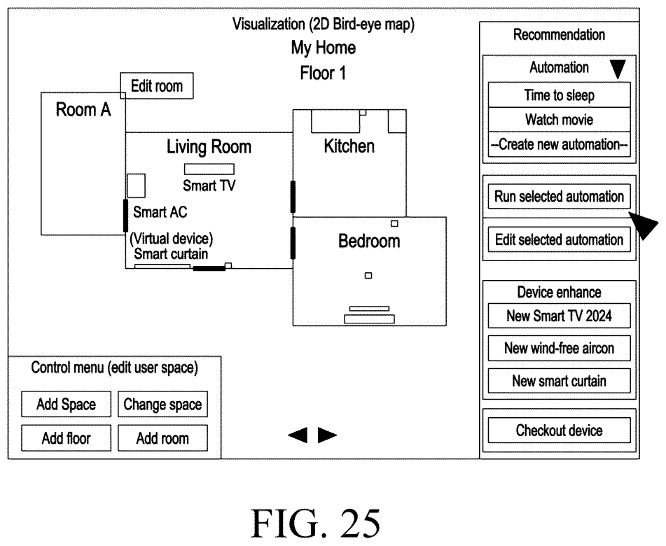

FIG. 25 is the experience UI wireframe. This figure shows the process when the user selects runs or edits a selected automation recommendation. Based on the user's selected automation recommendation, the user could choose to run the selected automation, or edit the given automation. Editing the automation works in a sense that the user could change how the IoT devices, both physical and virtual devices, behave in a given circumstance. Specifically, if the user chooses to edit existing automations, the user could add new rule(s) to accommodate the new virtual devices.

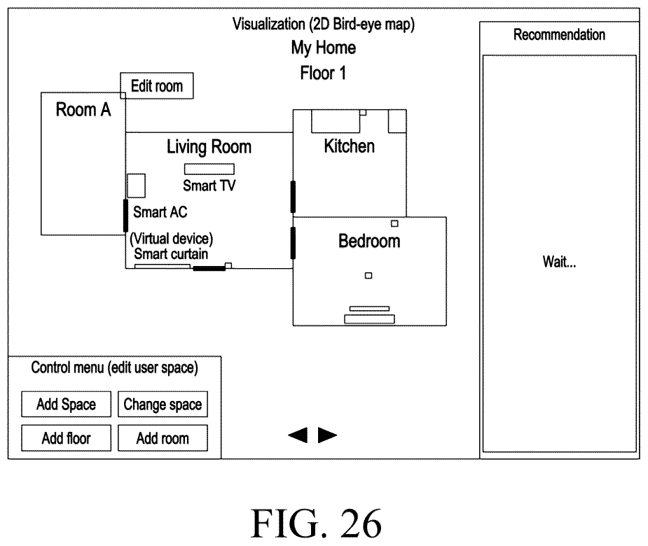

FIG. 26 is the Experience UI Wireframe. This figure shows the process when the user runs a selected automation recommendation. When a user runs a selected automation recommendation, the automation will execute both in the physical and virtual devices. An animation for the selected automation would be initialized on the user space. On the user device IoT platform, virtual device added and selected automation would run according to the given automation. This would provide the user with an experience of feeling the selected automation running on their physical devices.

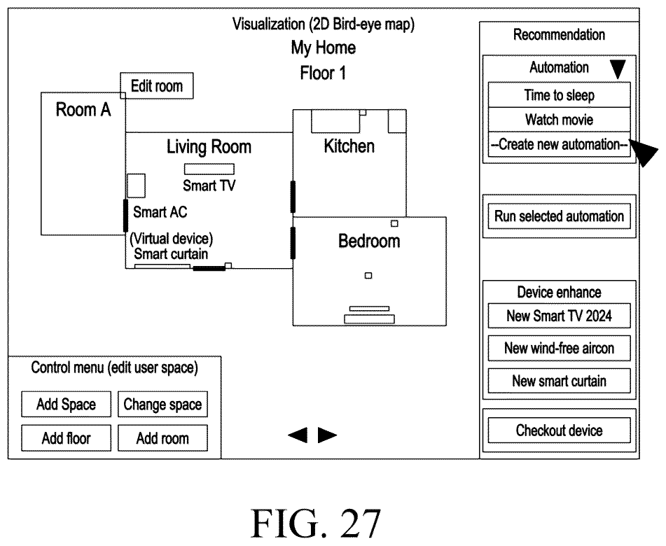

FIG. 27 is the experience UI wireframe. This figure shows the process when the user creates a new automation. Not only applying the available automation recommendations, the user may also choose to create their own automation, including those that facilitates the virtual devices which the user has already created. This may be done by adding new automation rules/sequences that includes all the virtual devices.

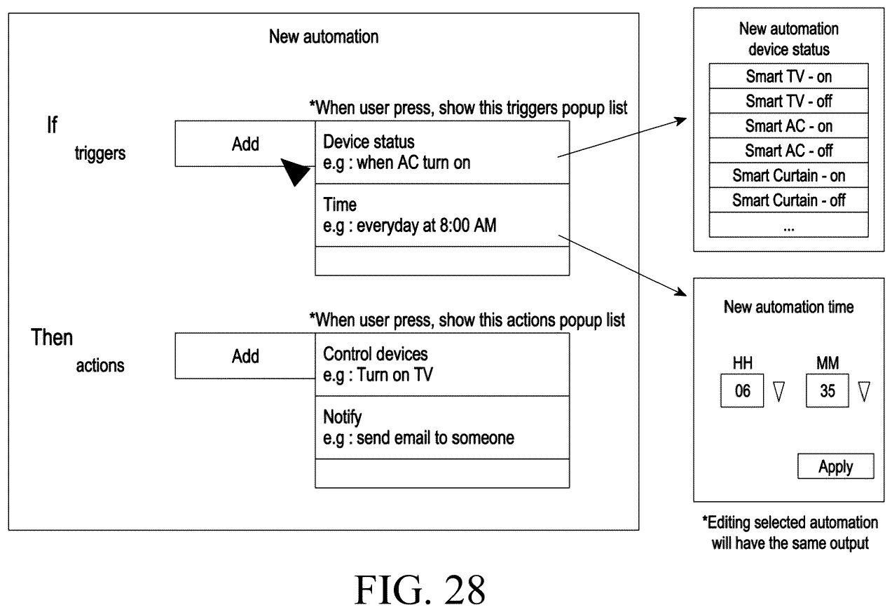

FIG. 28 is the experience UI wireframe. This figure shows the process when the user creates a new automation and customizes “if triggers” events. Upon choosing to add new automations, accommodating both physical and virtual devices, the user could customize each “if triggers” events, or events that would trigger the execution of other events individually, allowing more than a single event as precondition for a following event. In the sample implementation, when the user clicks on add “New Automation” they could add multiple “if triggers”, with device status and time as options of events, where each event could be specified further.

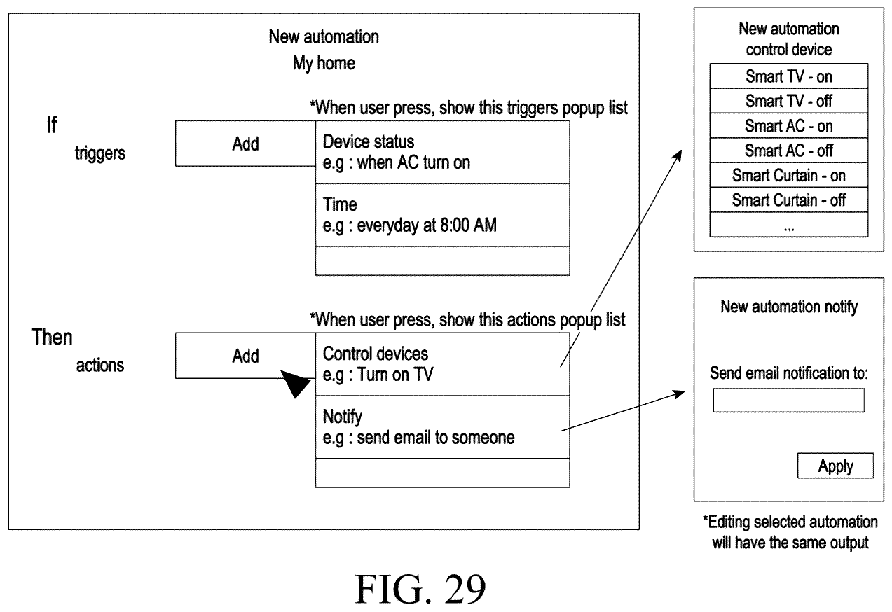

FIG. 29 is the experience UI wireframe. This figure shows the process when the user creates a new automation and customizes “then actions” events. Not only more than a single event as preconditions, the system also allows multiple “then actions” or actions that happen as a result to the preconditions being met. This provides the user with a flexibility to customize how their devices act as multiple devices could execute actions based on the given “if triggers”. In the sample implementation, when the user clicks on add “New Automation” they could add multiple “the actions”, with control devices and notifications as options of events, where each event could be specified further.

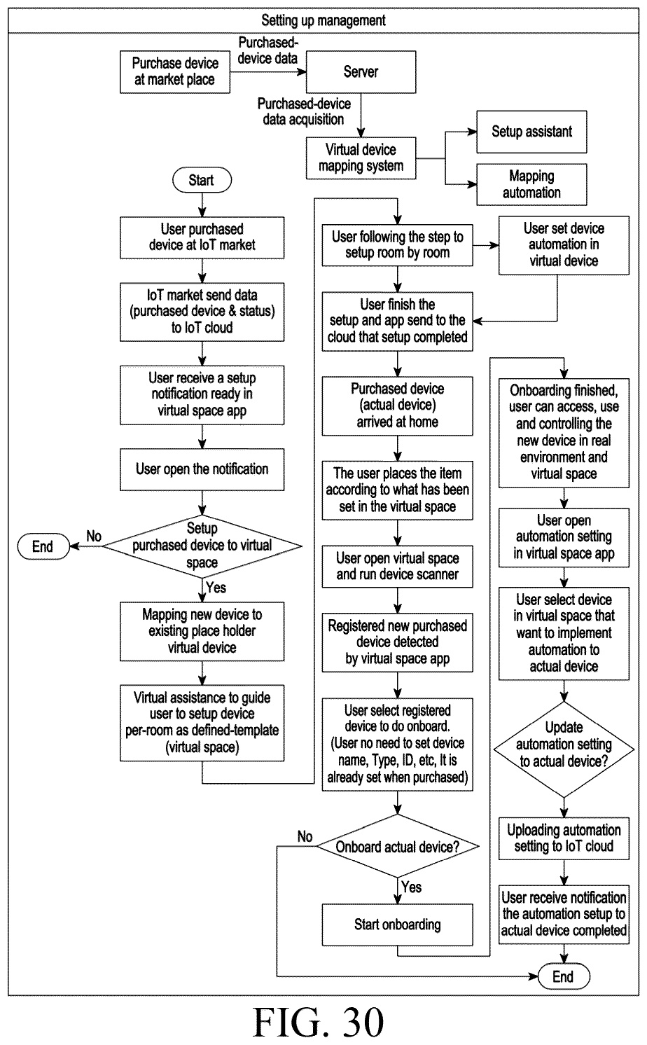

FIG. 30 is the overview of setting up subsystem. When a user purchases an IoT device from an IoT marketplace, relevant device data including device type, serial number, and user ID are uploaded to the server. Users may received a setup notification for their newly acquired device, prompting the virtual device mapping system to process the acquired data for mapping to an existing placeholder of a virtual device. The virtual device mapping system generates a setup assistant and mapping automation tailored to the user's needs. The setup assistant aids in implementing the onboarding process from the virtual device to the actual device, while the mapping automation facilitates the mapping of the device from the virtual device placeholder to the real device. Once the physical device arrives at the user's location, they may position it according to the setup instructions generated by the virtual space app. During the onboarding process, the user may skip manual input of device information such as name, ID, type, or serial number; instead, they simply scan and select the desired device for setup, which is limited to devices previously registered with the system at the time of purchase.

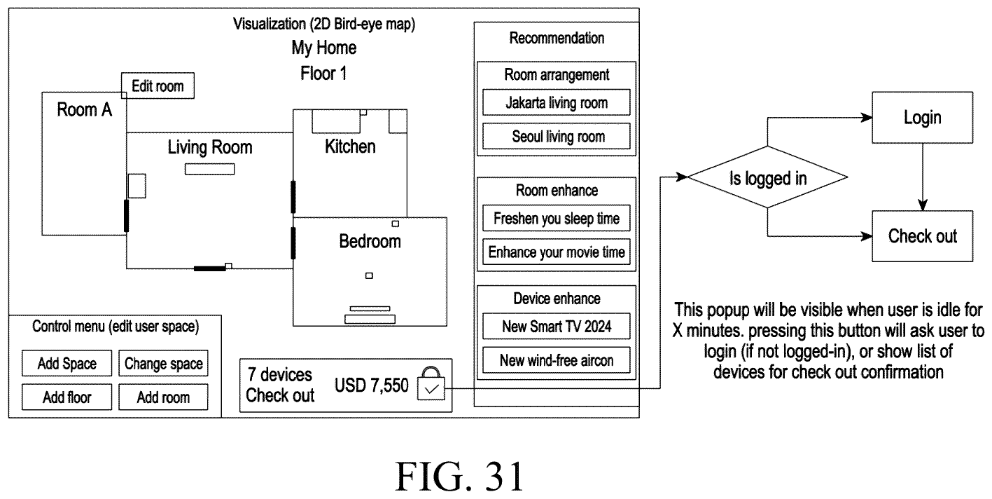

FIG. 31 is the checkout UI wireframe. This figure shows the event when the user has completed adding the desired recommendations. The system would give the user an option to check out all the devices added based on the recommendations. This process leads the user to a login page for the user to login with their designated accounts, providing the user with a check-out confirmation with the list of added items, which the user could proceed to checkout.

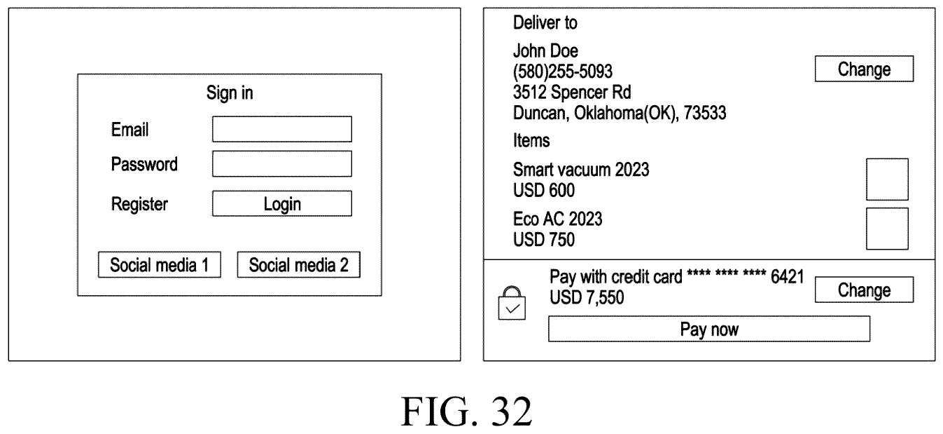

FIG. 32 is the checkout UI wireframe. This figure shows the event when the user chooses to check-out the added devices. After the user has decided to proceed with purchasing the recommended devices, the user would need to login with their designated platform or social media account, which leads them to a check-out page, consisting of an address confirmation, list of items to be purchased, and payment options, which are all customizable by the user. Upon this stage, the user may proceed to pay for the selected products.

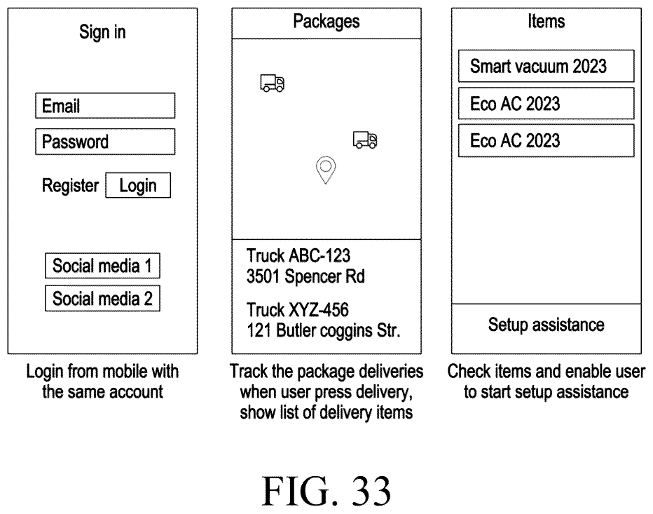

FIG. 33 is the checkout UI wireframe. This figure shows the process when the user checks the delivery status of their purchased devices. Upon checking out and purchasing the recommended devices, the user could check the delivery status of their purchased devices. After receiving the devices, the user could proceed to the Setup Assistance stage, where the system would provide on-boarding steps for each device.

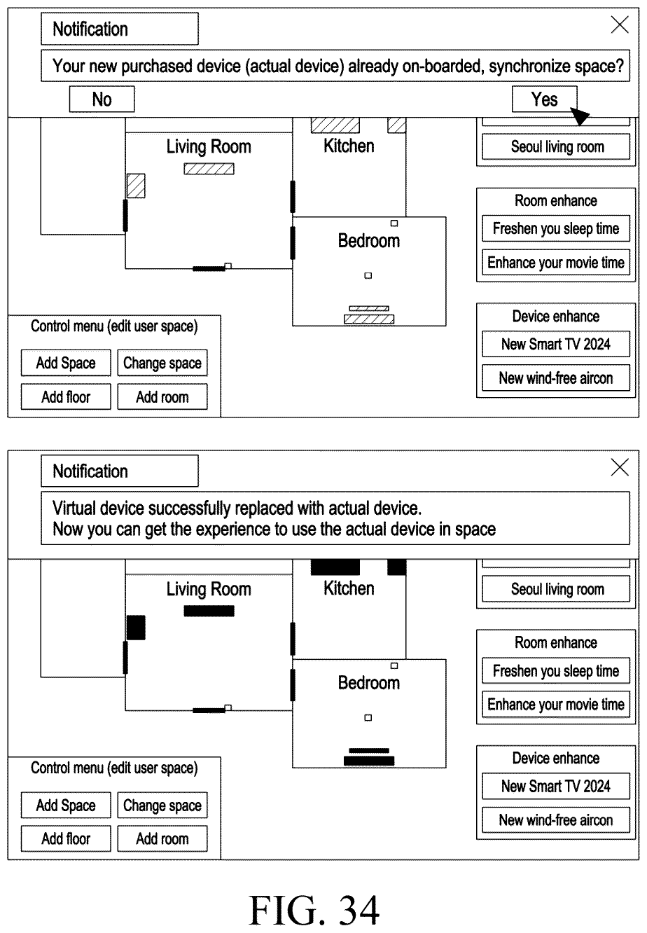

FIG. 34 is the setup assistance UI wireframe. This figure shows the event when the user has completed the on-boarding process and synchronizes the space with the newly added devices. Upon completion of the on-boarding for all the purchased devices, the system would re-synchronize with all the newly added devices, adding them into the user space and replacing virtual devices within the space with actual devices. This would in turn provide new recommendations for the user, now accommodating the new devices currently in place.

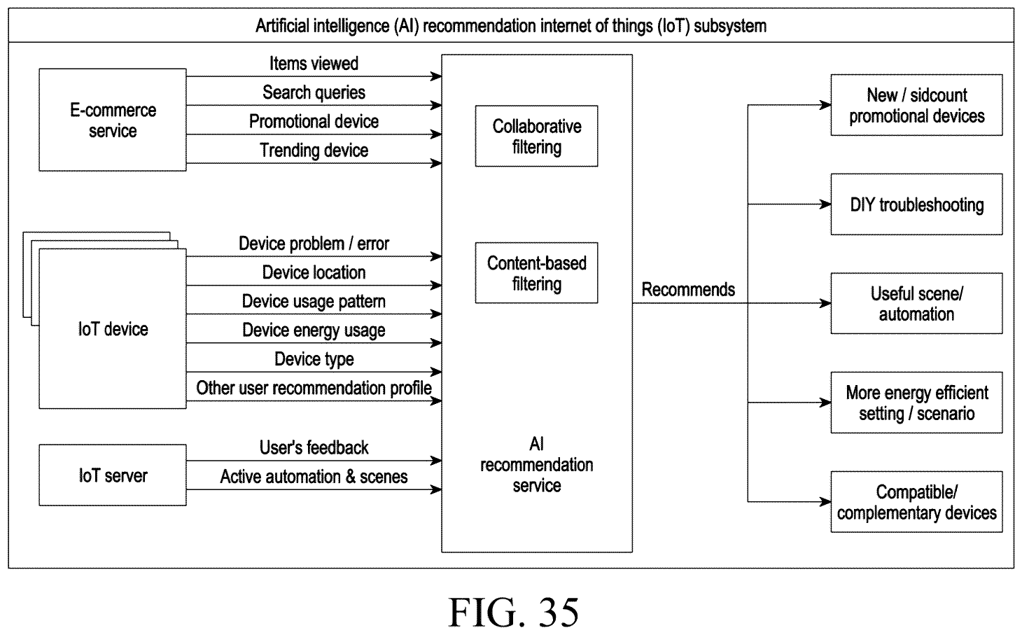

FIG. 35 is the IoT AI recommendation subsystem. The AI recommendation system delivers personalized recommendations based on inputs from e-commerce services, comprising promotional and trending devices, user search queries, and viewed items, as well as data from the user's IoT devices, encompassing device issues, location, usage patterns, energy consumption, and type. Additionally, the system incorporates server-side information such as other user recommendation profiles and feedback. The AI recommendation system offers suggestions for new or discounted devices, solution to troubleshooting, beneficial scene automation, energy-efficient scenarios, and compatible or complementary devices. To generate recommendations, the system employs collaborative filtering to suggest other users' interests potentially suited to the current user, and content-based filtering to recommend features aligned with the user's preferences. Over time, the AI recommendation service continually improves based on user feedback and acceptance of previous recommendations.

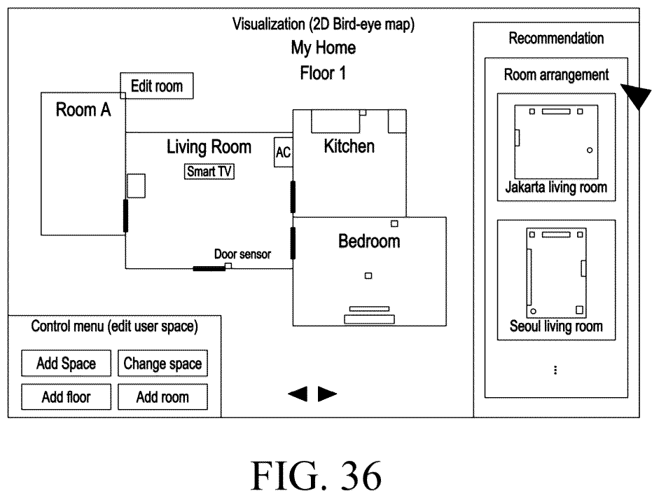

FIG. 36 is the room arrangement UI wireframe. This figure shows the process when the user views room arrangement recommendations. Upon selecting a room arrangement recommendation, the user could implement the IoT devices in the selected arrangement along with its layout within their user space. In the sample implementation, room arrangement recommendations could be accessed via the recommendations tab on the right.

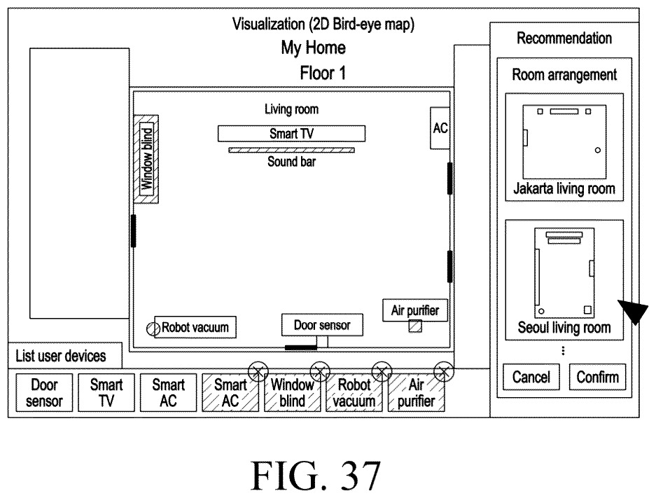

FIG. 37 is the room arrangement UI wireframe. This figure shows the process when the user selects a room arrangement recommendation. After selecting the preferred room arrangement recommendation, the selected room would be highlighted, showing the items within the recommended arrangement and its relative placement in the corresponding room. The user is able to customize each device in the arrangement as a group and as its own.

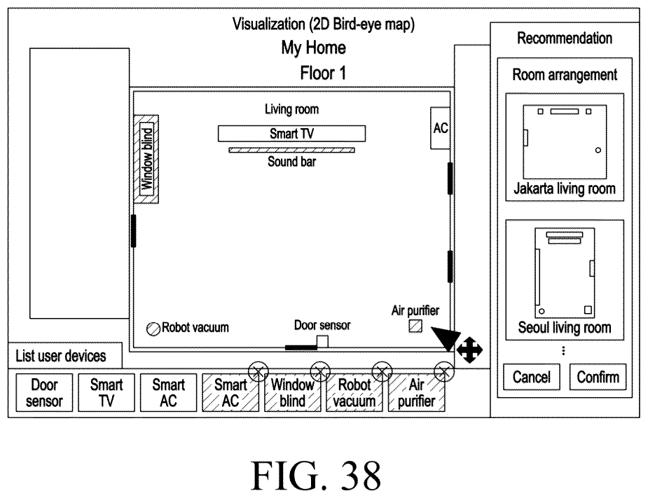

FIG. 38 is the room arrangement UI wireframe. This figure shows the process when the user moves/customizes a room arrangement recommendation. After placing the selected room arrangement recommendation, the user is able to customize each device in the arrangement as a group and as its own, moving the relative placing of each device upon each other.

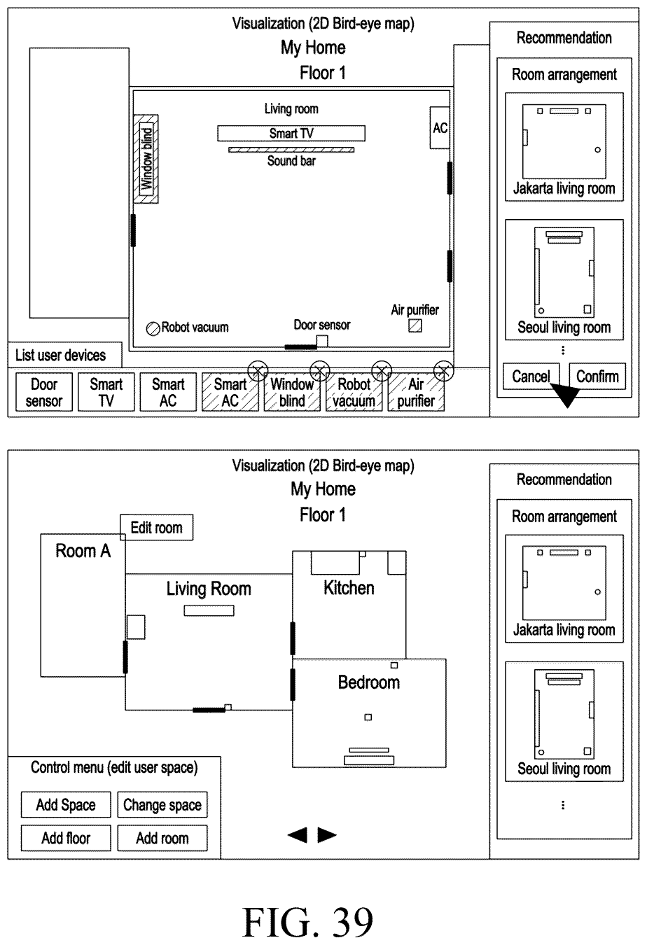

FIG. 39 is the room arrangement UI wireframe. This figure shows the event when the user chooses to cancel the application of the selected room arrangement recommendation. Despite already being selected, scaled, and customized, the selected room arrangement recommendation applied could be canceled by user. In the sample implementation, the user could click the “Cancel” button within the room arrangement recommendation tab.

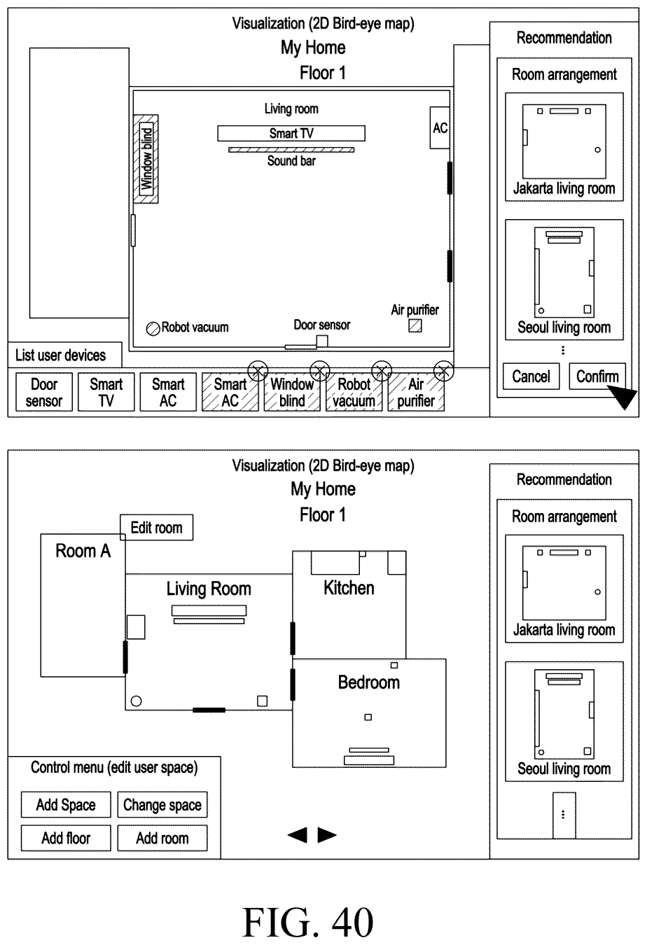

FIG. 40 is the room arrangement UI wireframe. The above figure shows the event when the user chooses to confirm and apply the application of the selected room arrangement recommendation. After the user has completed the scaling, positioning, and customizing each device within the selected room arrangement recommendation, the user could choose to implement the selection and which will change the designated layout within the user space. In the sample implementation, this could be done by clicking the “Confirm” button within the room arrangement recommendation tab.

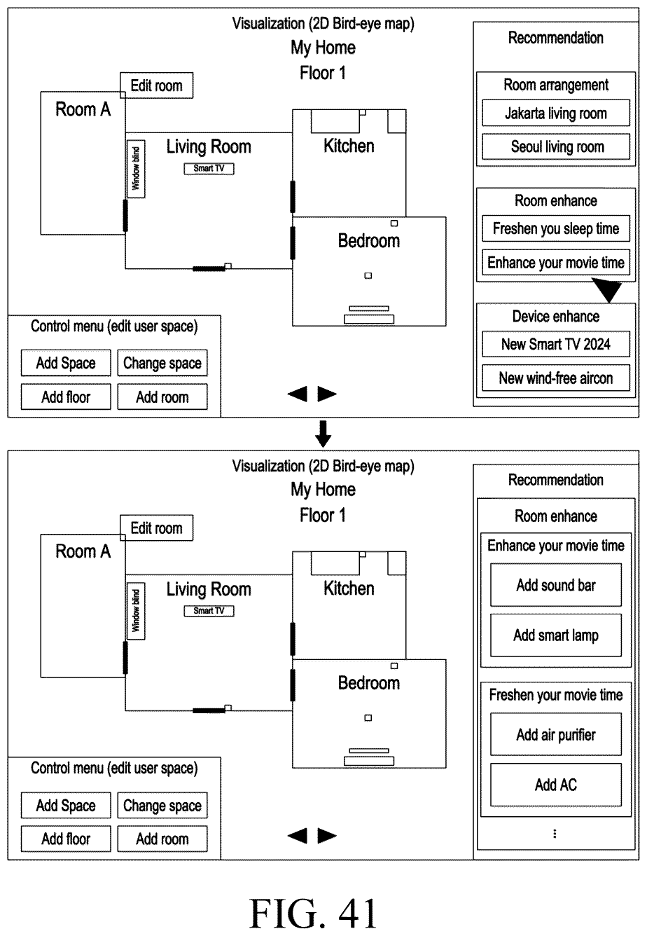

FIG. 41 is the room enhance UI wireframe. The above figure shows the event when the user chooses to select room enhancement recommendations. For rooms with existing IoT devices in each floor, the system would create recommendations which could enhance the user's IoT visualization and experience, especially by suggesting additional possible devices which could act as supplementary for the already available IoT devices/environment. In the sample implementation, this could be accessed via the room enhance recommendation tab.

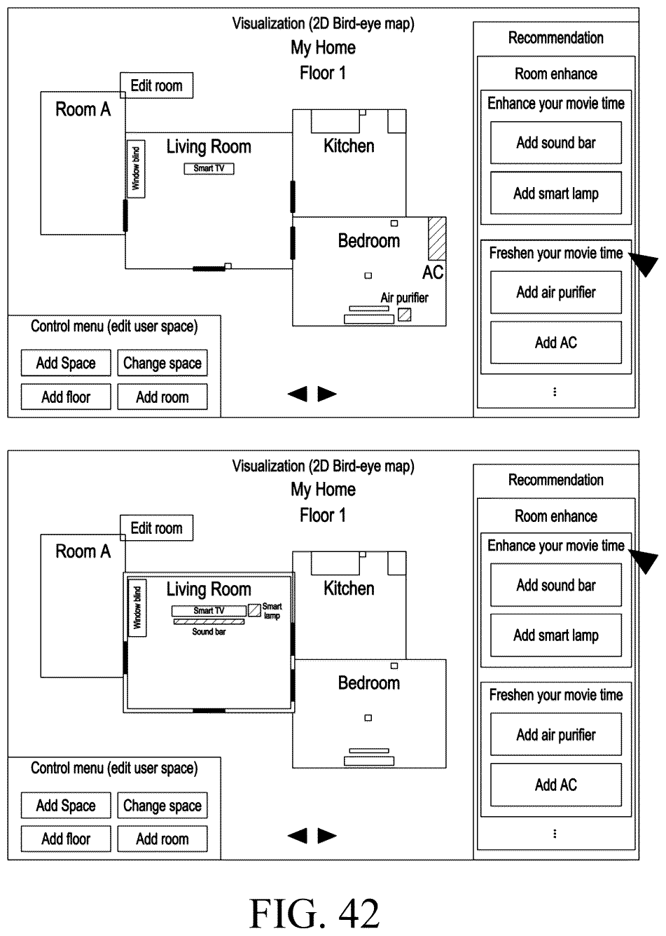

FIG. 42 is the room enhance UI wireframe. This figure shows the event when the user chooses to select a given room enhancement recommendation. Based on the given room enhancement recommendations, the user could select the recommendation which appeals to them the most. When hovering over the given recommendation, the system would highlight the room which the recommendation refer to.

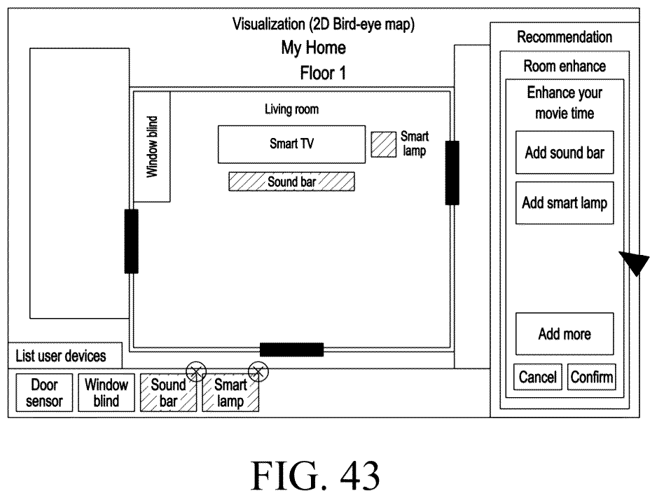

FIG. 43 is the room enhance zoom in UI wireframe. This figure shows the process when the selects on a room enhance recommendation. Upon selecting a specific room enhancement recommendation from the given recommendations, the system would highlight the room correlating to the selected recommendation, with the virtual devices being part of the recommendation already placed within the room. The user would be able to view the currently available devices, both physical and virtual, within that particular room. In addition to this, the user could also add more devices outside of the recommendation as to their requirements.

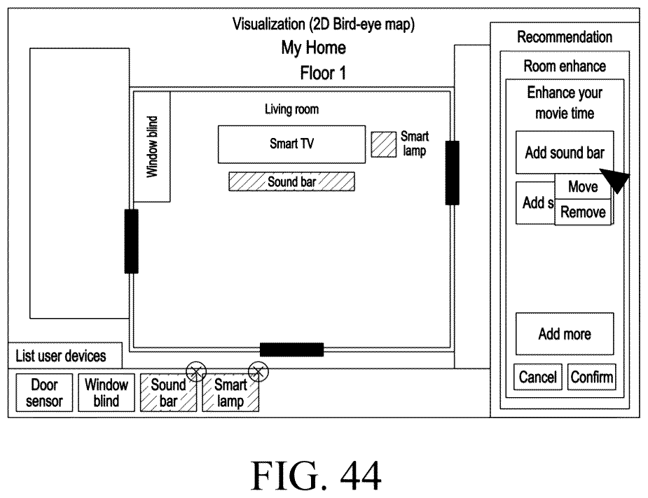

FIG. 44 is the room enhance zoom in UI wireframe. This figure shows the process when the user customizes a device within a room enhancement recommendation. After adding virtual devices based on the selected recommendation, the user could customize each device within that recommendation, namely moving the devices around the room or removing the device. In the sample implementation, these could be accessed by right-clicking on the device within the selected recommendation tab.

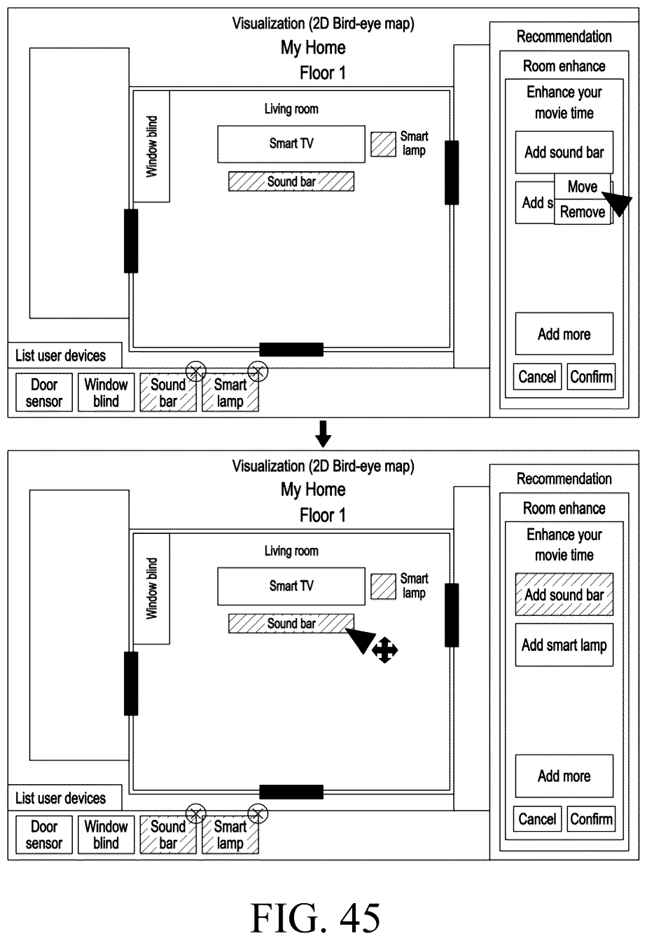

FIG. 45 is the room enhance zoom in UI wireframe. This figure shows the event when the user chooses to move a specific device within a room enhancement recommendation. Each virtual device placed by the system based on the room enhancement recommendation could be moved around the room. In the sample implementation, this could be done by clicking on the “Move” button after right-clicking the selected device within the selected room enhancement recommendation.

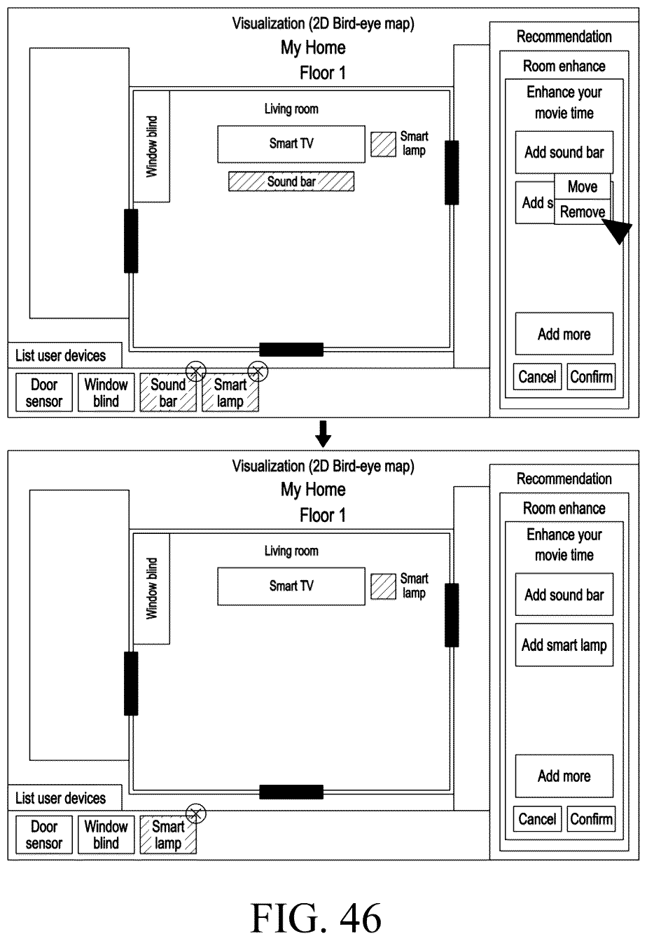

FIG. 46 is the room enhance zoom in UI wireframe. This figure shows the event when the user chooses to remove a specific device within a room enhancement recommendation. Each virtual device placed by the system based on the room enhancement recommendation could be removed from the room. This would also remove the selected virtual device from the list of user devices within the room. In the sample implementation, this could be done by clicking on the “Remove” button after right-clicking the selected device within the selected room enhancement recommendation.

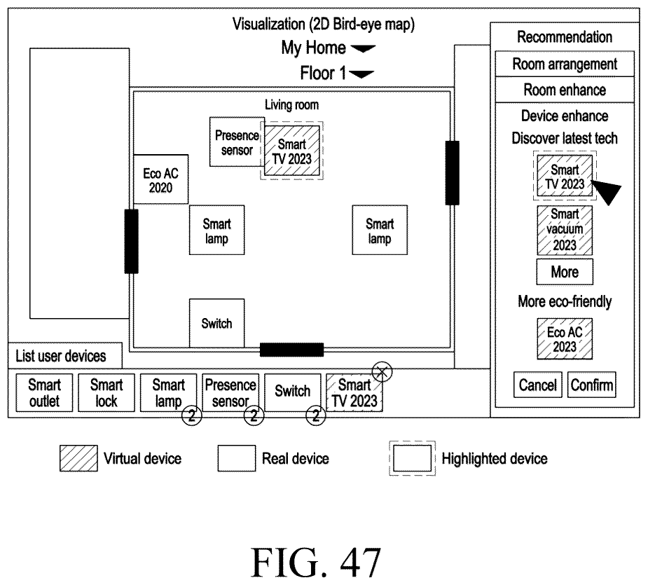

FIG. 47 is the device recommendation UI wireframe. This figure shows the process when the user selects a device enhancement recommendation. Based on the user's currently available IoT devices, the system makes upgrade recommendations for which device upgrades are available, which helps the user in preventing outdated devices, and easing the process of upgrading their outdated devices into the latest ones. When the user selects on a particular device enhancement, the system would directly highlight the room(s) in which the specific device is located, and provides a recommended device positioning for the new device. In the sample implementation, this may be accessed via the “Device Enhance” tab in the recommendations section of the platform.

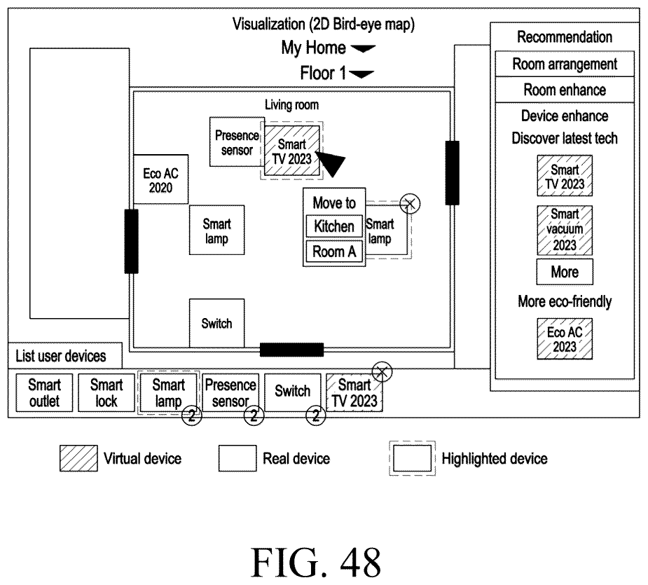

FIG. 48 is the device recommendation UI wireframe. This figure shows the process when the user moves a device into from one room into another. In order to help ease the user's layout planning process, the system enables the user to move their virtual devices into another room. Such conditions appear when based on the device enhancement recommendations given by the system, the user feels that the newly upgraded device should be placed in another room, aside from the current room being recommended by the system. Upon moving, the virtual device will be removed from the list of user devices within the current room and will be added in the selected room instead. In the sample implementation, this could be done by right-clicking the selected virtual device, and choosing a designated room for the virtual device to be moved to.

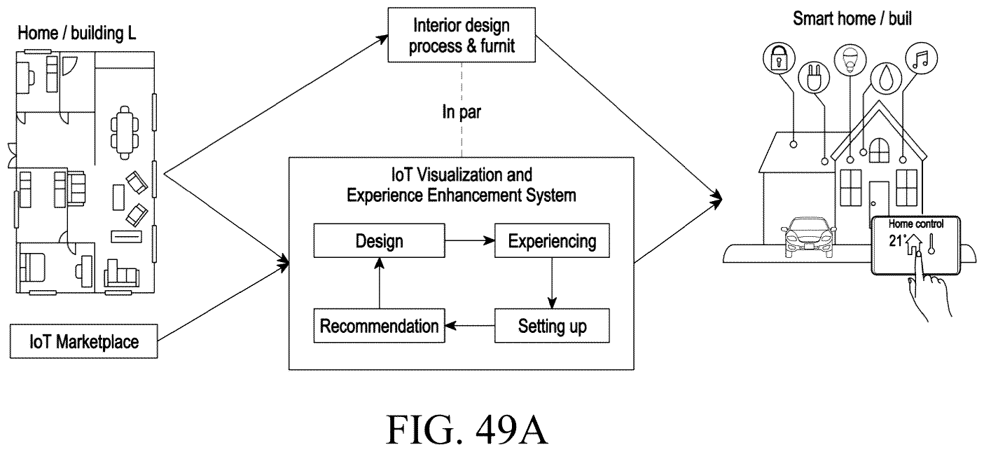

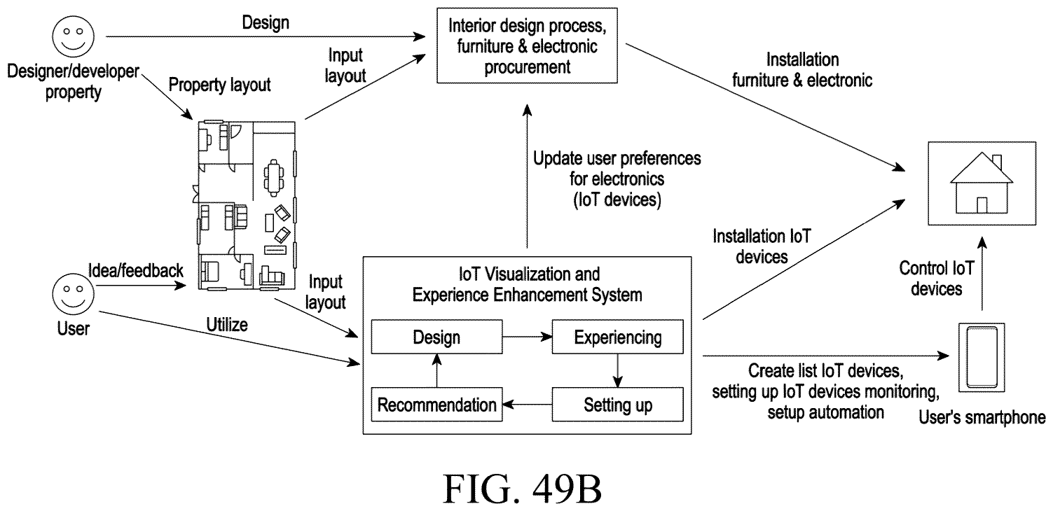

FIGS. 49A and B are exemplary diagrams illustrating the use case developing a smart infrastructure (home, apartments, building, etc.). When developing a smart infrastructure, such as a home, apartment, or building from scratch, users face multiple challenges. They must conduct extensive research, plan, and integrate each IoT device, considering numerous manufacturers and constant updates. By utilizing the proposed system, users may streamline this process. Based on the layout design, they may plan, experience, purchase, and set up IoT devices individually or as a whole, avoiding the need to separately plan the building design and install devices. Users may instantly create a single ecosystem, eliminating the need for research and mix-matching devices from different manufacturers.

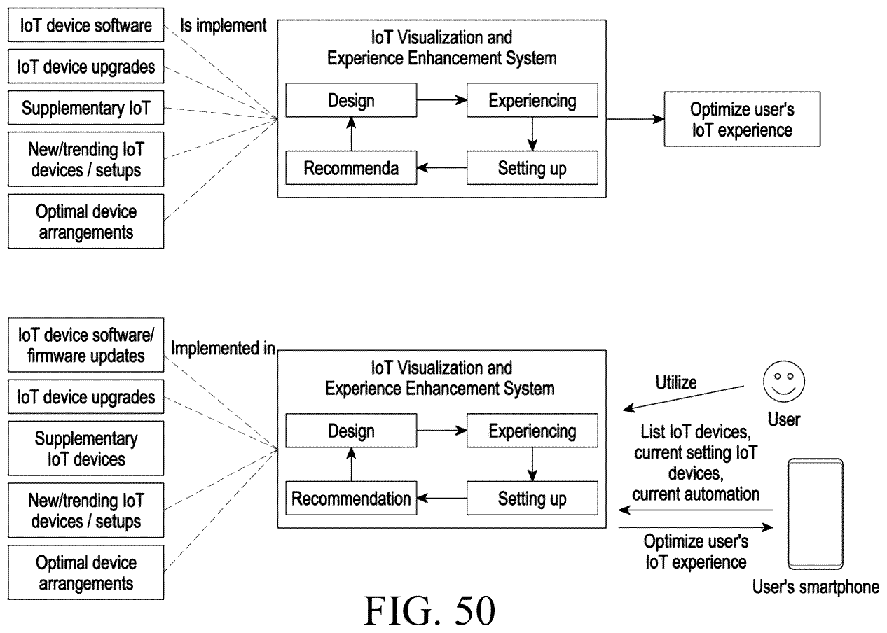

FIG. 50 is the use case maintenance of currently available IoT devices and enhancement of user's IoT visualization and experience. When maintaining currently available IoT devices and enhancing the user's IoT visualization and experience, users often feel overwhelmed by the vast amount of resources online, making decisions on potential capabilities challenging. System updates may also significantly impact the user experience, leading to confusion in selecting the correct patches or prioritizing device upgrades. These complexities increase due to the variety of manufacturers and cross-compatibility attributes.

By providing recommendations, the system simplifies the decision-making process for users. It helps overcome update issues, such as outdated devices no longer supported by manufacturers or software patches addressing specific security vulnerabilities. Compatibility and functionality attributes are managed by the system, which also introduces new devices to replace or supplement current setups. This addresses users' concerns about enhancing their IoT visualization and experience while discovering unanticipated experiences. From a marketing perspective, these introductions and recommendations may promote the purchase of newly launched products or product sets, catering to users seeking more from their IoT environment.

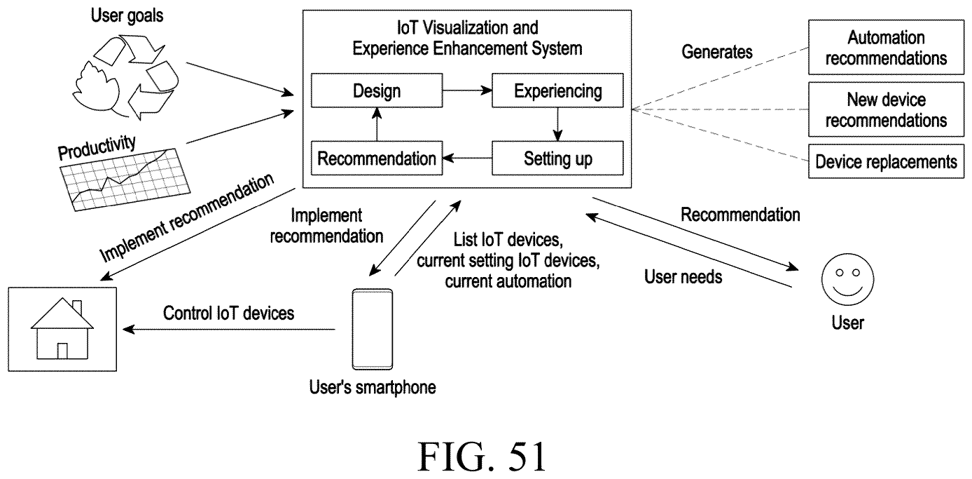

FIG. 51 is use case customize user's IoT environment according to specific goals. All users possess unique goals they wish to accomplish using their IoT environment. Goals may involve reducing environmental impacts of electricity consumption via energy-efficient setups or increasing productivity and improving time management. Multiple approaches and actions incorporating automations, smart devices, and personalized settings may be implemented using the user's IoT environment to achieve these goals.

To realize their objectives, the system offers targeted recommendations tailored to each user's goals. For energy-saving scenarios, the system suggests creating automations that maintain only essential electronic devices during specific times or recommending new energy-efficient devices as replacements for older ones, promoting the user's goals. For users aiming for increased productivity, the system recommends replacing or adding smart household devices, such as smart washing machines, remote vacuum cleaners, and refrigerators, and providing device automations. This reduces the time spent on chores, allowing more time for other priorities.

What is claimed is:

1. An apparatus for enhanced user visualization of internet of things (IoT) capabilities of a plurality of IoT devices, the apparatus comprising:
memory storing instructions; and
at least one processor; and
wherein the instructions, when executed by the at least one processor, cause the apparatus to:
display a modular floor plan based on an area associated with a user;
map placement of one or more existing IoT devices associated with the user on the modular floor plan;
recommend a new IoT device by displaying the new IoT device on the modular floor plan, wherein the new IoT device is compatible with the one or more existing IoT devices;
scan the new IoT device in response to confirmation that the user received the new IoT device; and
map the new IoT device to an existing placeholder IoT device from the modular floor plan.

2. The apparatus of claim 1, wherein the instructions, when executed by the at least one processor cause the electronic device to:
receive a space layout based on the area associated with the user;
determine one or more floors in the space layout;
for each of the one or more floors, determine one or more rooms based on the space layout; and
generate the modular floor plan based on the one or more floors and the one or more rooms.

3. The apparatus of claim 2, wherein the instructions, when executed by the at least one processor cause the electronic device to:
adjust positions of the one or more existing IoT devices associated with the user on the modular floor plan in response to under input; or
adjust the positions of the one or more existing IoT devices associated with the user on the modular floor plan based on recommended positions.

4. The apparatus of claim 1, wherein the instructions, when executed by the at least one processor prior to scanning the new IoT device, further cause the apparatus to:
display an automation experiencing interface compatible with the one or more existing IoT devices and the new IoT device.

5. The apparatus of claim 1, wherein the instructions, when executed by the at least one processor cause the electronic device to:
detect the new IoT device, and
display prompts assisting the user in setting up the new IoT device.

6. The apparatus of claim 1, wherein the recommending the new IoT device is based on device configurations of the one or more existing IoT devices associated with the user.

7. A method for enhanced user visualization of internet of things (IoT) capabilities of a plurality of IoT devices, the method comprising:
displaying a modular floor plan based on an area associated with a user;
mapping placement of one or more existing IoT devices associated with the user on the modular floor plan;
recommending a new IoT device by displaying the new IoT device on the modular floor plan, wherein the new IoT device is compatible with the one or more existing IoT devices;
scanning the new IoT device in response to confirmation that the user received the new IoT device; and
mapping the new IoT device to an existing placeholder IoT device from the modular floor plan.

8. The method of claim 7, wherein the displaying the modular floor plan comprises:
receiving a space layout based on the area associated with the user;
determining one or more floors in the space layout;
for each of the one or more floors, determining one or more rooms based on the space layout; and
generating the modular floor plan based on the one or more floors and the one or more rooms.

9. The method of claim 8, wherein the mapping the placement of the one or more existing IoT devices comprises:
adjusting positions of the one or more existing IoT devices associated with the user on the modular floor plan in response to under input; or
adjusting the positions of the one or more existing IoT devices associated with the user on the modular floor plan based on recommended positions.

10. The method of claim 7, wherein the method further comprises:
displaying an automation experiencing interface compatible with the one or more existing IoT devices and the new IoT device.

11. The method of claim 7, wherein the scanning of the new IoT device comprises:
detecting the new IoT device, and
displaying prompts assisting the user in setting up the new IoT device.

12. The method of claim 7, wherein the recommending the new IoT device is based on device configurations of the one or more existing IoT devices associated with the user.

13. A non-transitory computer readable medium storing instructions, that when executed by at least one processor for enhanced user visualization of internet of things (IoT) capabilities of a plurality of IoT devices, cause the at least one processor to:
display a modular floor plan based on an area associated with a user;
map placement of one or more existing IoT devices associated with the user on the modular floor plan;
recommend a new IoT device by displaying the new IoT device on the modular floor plan, wherein the new IoT device is compatible with the one or more existing IoT devices;
scan the new IoT device in response to confirmation that the user received the new IoT device; and
map the new IoT device to an existing placeholder IoT device from the modular floor plan.

14. The non-transitory computer readable medium of claim 13, wherein the instructions, when executed by the at least one processor, cause the at least one processor to:
receive a space layout based on the area associated with the user;
determine one or more floors in the space layout;
for each of the one or more floors, determine one or more rooms based on the space layout; and
generate the modular floor plan based on the one or more floors and the one or more rooms.

15. The non-transitory computer readable medium of claim 14, wherein the instructions, when executed by the at least one processor, cause the at least one processor to:
adjust positions of the one or more existing IoT devices associated with the user on the modular floor plan in response to under input; or
adjust the positions of the one or more existing IoT devices associated with the user on the modular floor plan based on recommended positions.

16. The non-transitory computer readable medium of claim 13, wherein the instructions, when executed by the at least one processor, cause the at least one processor to:
display an automation experiencing interface compatible with the one or more existing IoT devices and the new IoT device.

17. The non-transitory computer readable medium of claim 13, wherein the instructions, when executed by the at least one processor, cause the at least one processor to:
detect the new IoT device, and
display prompts assisting the user in setting up the new IoT device.

18. The non-transitory computer readable medium of claim 13, wherein the recommending the new IoT device is based on device configurations of the one or more existing IoT devices associated with the user.
